(19) United States
(12) Patent Application Publication
(10) Pub. No.: US 2016/0351443 A1
(43) Pub. Date: Dec. 1, 2016

(54) INORGANIC ALD FILM ON AN ORGANIC POLYMER SURFACE

(71) Applicants: Steven M. GEORGE, Boulder, CO (US); John D. FERGUSON, Broomfield, CO (US); Alan W. WEIMER, Niwot, CO (US); Christopher A. WILSON, Central, SC (US)

(72) Inventors: Steven M. GEORGE, Boulder, CO (US); John D. FERGUSON, Broomfield, CO (US); Alan W. WEIMER, Niwot, CO (US); Christopher A. WILSON, Central, SC (US)

(73) Assignee: REGENTS OF THE UNIVERSITY OF COLORADO a Body Corporate, DENVER, CO (US)

(21) Appl. No.: 15/168,006

(22) Filed: May 28, 2016

Related U.S. Application Data
(63) Continuation-in-part of application No. 10/482,627, filed on Dec. 26, 2003, now Pat. No. 9,376,750.
(60) Provisional application No. 60/306,521, filed on Jul. 18, 2001.

(51) Int. Cl. H01L 21/768; H01L 21/02; C01F 7/30; C08F 110/02; C08F 110/06; C23C 16/34; C08F 112/08; C08G 64/00; C08F 130/08; C08G 73/10; C23C 16/455; C23C 16/06; H01L 23/532; C08F 120/10

(52) U.S. Cl. CPC H01L 21/76867; H01L 23/5329; H01L 21/0228; C01F 7/304; C08F 110/02; C08F 110/06; C08F 120/10; C08F 112/08; C08G 64/00; C08F 130/08; C08G 73/10; C23C 16/45525; C23C 16/06; C23C 16/34

(57) ABSTRACT

The present invention relates to a method and a composition comprising a polymer substrate having free volume and/or a porous surface; and an inorganic film layer comprising a metal oxide or nitride at least partially covering the polymer substrate.

### RELATED APPLICATIONS

This application is a Continuation in Part of co-pending U.S. application Ser. No. 10/482,627 filed on Dec. 26, 2003, now allowed, which is the U.S. National Stage of International Application No. PCT/US2002/022742, filed Jul. 16, 2002, which designates the U.S., published in English, and claims the benefit of U.S. Provisional Application No. 60/306,521, filed Jul. 18, 2001. The entire teachings of the above applications are incorporated herein by reference.

### BACKGROUND OF THE INVENTION

For various reasons, inorganic coatings on polymers are expected to provide desirable properties. For example, the gas permeability through most polymers is quite high for gases such as hydrocarbons, H₂O and O₂. This gas permeability affects the quality of polymers used for food and medical packaging. H₂O vapor and O₂ can diffuse into the polymer package material from the outside and degrade the package contents. Inorganic films, such as Al₂O₃ and SiO₂ films are much less permeable than polymers. Such inorganic films could potentially form a diffusion barrier to prevent gas permeability in polymer films.

In the area of microelectronics, polymers are used as low dielectric constant (low k) insulating films. Deposition on these low k films is difficult. The deposition of an oxide layer on the polymer substrate surface may provide a base surface layer that allows deposition of other materials. One such material is titanium nitride, which is used as a copper diffusion barrier.

Deposition of inorganic films on organic polymer surfaces is difficult. Chemical Vapor Deposition (CVD) methods usually cannot be used because the CVD temperatures are above the softening or pyrolysis temperatures for the polymers. Physical sputtering or plasma deposition can be employed at low temperatures to form oxide films such as Al₂O₃ or SiO₂. However, sputtering requires line-of-sight to the polymer surface and is not effective for shadowed structures or particles. Plasma deposition involves high-energy particles that can damage and corrode the polymer surface. Both sputtering and plasma deposition also leave defects and pinholes in the deposited inorganic film that provide paths for H₂O and O₂ gas diffusion through the inorganic film. Both of these characteristics are important for applications in food and medical packaging that require a transparent diffusion barrier on the polymer surface.

In addition, sputtering requires a special apparatus and high maintenance sputtering targets. More significantly, sputtering is not effective for coating shadowed structures or particles, because sputtering can coat only a limited area and requires line-of-sight to the polymer surface. Plasma deposition also requires a plasma generation source and involves high-energy species. Although these species can react with the polymer and functionalize the surface, they can also corrode the polymer. Consequently, the plasma deposition of oxide films can damage the underlying organic polymer substrate.

For at least these reasons, it would be desirable to provide organic polymers having thin deposits of inorganic materials adhered to the polymer. It would also be desirable to provide a method to deposit very thin coatings of inorganic materials onto polymer substrates.

At the time of our invention, to our knowledge, atomic layer deposition (ALD) had not been used to form an alumina coating on a polymer. The general view was that, in order to initiate the ALD of metal oxides on a surface upon exposure of the metal source, the surfaces must be terminated with hydroxyl groups. (See, e.g., Haukka, S., et al. J. Phys. Chem. 1993, 97, 5085; and Matra, R., et al., Thin Solid Films 2000, 368. Other published studies have shown evidence that, from a thermodynamics perspective ALD should not grow on substrates without hydroxyl (—OH) groups on the surface. (See, e.g., “A DFT Study of the Al₂O₃ Atomic Layer Deposition on SAMs: Effect of SAM Termination,” Ye Xu and Charles B. Musgrave, Chem. Mater. 16, 646-653, 2004.)

### SUMMARY OF THE INVENTION

The invention inter alia includes the following, alone or in combination. One embodiment of the invention is a composition comprising: a polymer substrate having free volume and/or a porous surface; and an inorganic film layer comprising a metal oxide or a transition metal nitride at least partially covering the polymer substrate. in one embodiment, the inorganic film layer has a thickness of about 200 nanometers or less.

In another embodiment of the invention the inorganic film layer of the disclosed composition is conformal and comprises at least one of aluminum oxide, titanium oxide, zinc oxide, a transition metal nitride, or a combination thereof.

In yet another embodiment of the invention, the inorganic film layer is ultrathin, and has a thickness of from about 0.1 nanometer to about 50 nanometers. In another embodiment, the thickness of the inorganic film layer is from about 0.5 nanometer to about 35 nanometers. Also disclosed herein is an embodiment wherein the thickness of the inorganic film layer is from about 1 nanometer to about 20 nanometers.

The inorganic film layer may be deposited on the polymer substrate by atomic layer deposition using a fluidized bed reactor, a rotary bed reactor, a vibrating bed reactor, or a combination of two or more of the aforementioned reactors.

The present invention has many advantages. For example, a disclosed composition may be fabricated into a container. Further, the inorganic film layer may provide a gas and vapor diffusion barrier for the container. Another embodiment, for example, wherein the polymer substrate is Kapton, may be used in space vehicles, wherein the inorganic film layer is positioned to deflect atoms, photons, and/or ions striking the composition.

### BRIEF DESCRIPTION OF THE DRAWINGS

The foregoing and other objects, features and advantages of the invention will be apparent from the following more particular description of illustrative embodiments of the invention, as illustrated in the accompanying drawings in which like reference characters refer to the same parts throughout the different views. The drawings are not necessarily to scale, emphasis instead being placed upon illustrating the principles of the invention.

FIG. 1A depicts the mass change at higher mass resolution measured by QCM versus number of AB cycles during Al₂O₃ ALD on PS at 85° C. for 30 AB cycles.

FIG. 1B shows the mass change at highest mass resolution versus number of AB cycles during Al₂O₃ ALD on PS at 85° C. for 5 AB cycles; and TMA and H₂O exposure sequence coinciding with mass changes is given for comparison.

FIG. 2A shows the mass change measured by QCM versus number of AB cycles during Al₂O₃ ALD on PP at 85° C. for 30 AB cycles.

FIG. 2B shows the mass change at higher mass resolution versus number of AB cycles during Al₂O₃ ALD on PP at 85° C. for 5 AB cycles, with TMA and H₂O exposure sequence coinciding with mass changes given for comparison.

FIG. 3A shows the mass change measured by QCM versus number of AB cycles during Al₂O₃ ALD on PMMA at 85° C. for 30 AB cycles.

FIG. 3B shows the mass change at higher mass resolution versus number of AB cycles during Al₂O₃ ALD on PMMA at 85° C. for 5 AB cycles.

FIG. 4A shows the mass change measured by QCM versus number of AB cycles during Al₂O₃ ALD on PE at 85° C. for 30 AB cycles.

FIG. 4B shows the mass change at higher mass resolution versus number of AB cycles during Al₂O₃ ALD on PE at 85° C. for 5 AB cycles.

FIG. 5A shows the mass change measured by QCM versus number of AB cycles during Al₂O₃ ALD on PVC at 85° C. for 30 AB cycles.

FIG. 5B displays the first 5 AB cycles at higher mass resolution.

FIG. 6A is a schematic representation of a model for Al₂O₃ ALD on polymer films showing a cross-section of polymer film represented by loosely packed circles.

FIG. 6B is a schematic representation of a model for Al₂O₃ ALD on polymer films showing Al₂O₃ nucleation clusters forming from H₂O reaction with TMA trapped in near surface region.

FIG. 6C is a schematic representation showing coalescence of Al₂O₃ clusters shown in FIG. 6B and closure of space between polymer chains.

FIG. 6D is a schematic representation showing formation of dense Al₂O₃ film that grows on top of polymer surface following the steps shown in FIG. 6A, FIG. 6B, and FIG. 6C.

### DETAILED DESCRIPTION OF THE INVENTION

A description of preferred embodiments of the invention follows. It will be understood that the particular embodiments of the invention are shown by way of illustration and not as limitations of the invention. At the outset, the invention is described in its broadest overall aspects, with a more detailed description following. The features and other details of the compositions and methods of the invention will be further pointed out in the claims.

Most polymers are porous or have substantial free volume. A more detailed description of polymer porosity and free volume is set forth below. Disclosed herein is a method for depositing an inorganic material onto the surface of an organic polymer that is porous and/or has free volume, the method using an initial nucleation phase which is not self-limiting. During the nucleation phase, the diffusion of Atomic Layer Deposition (ALD) precursors such as trimethyl aluminum (TMA) and dimethylaluminum (DMA) into these organic polymer substrates leads to growth of Al₂O₃ that is much larger than that of previously known “classic self-limiting ALD growth.”

Following the nucleation phase, the disclosed method allows formation of a diffusion barrier, a susbstantially impermeable layer of inorganic material such as a metal oxide or a transition metal nitride, for example, Al₂O₃, TiO₂, ZnO₂, Fe₂O₃, TiN. Formation of the diffusion barrier is evidenced by the experimental results set forth in detail below.

An important distinction of our invention is the initial or nucleation steps which may require 10-15 atomic layer deposition (“ALD”; also known as ALE—“atomic layer epitaxy”) reaction cycles. Only after this nucleation period, and after formation of the diffusion barrier, the disclosed method follows classical ALD. After 10-15 cycles, there is a continuous inorganic sheet or ALD barrier on the polymer, the continuous inorganic sheet preventing the precursors from diffusing into the polymer. After the ALD barrier has been formed on the polymer, then the growth of the inorganic layer proceeds according to classical ALD in a self-limiting manner.

ALD techniques permit the formation of inorganic deposits approximately equal to the molecular spacing of the inorganic material, typically up to about 0.3 nm of thickness per reaction cycle, In the classical ALD process which follows nucleation and barrier formation, the inorganic deposit is formed in a series of two or more self-limited reactions. These self-limiting reactions in most instances can be repeated to sequentially form additional material until the inorganic deposit achieves a desired size or thickness.

A wide variety of polymers may be used as substrates, in particular those having free volume. Free volume is the fraction of the volume not occupied by the polymer. Some polymers have more free volume than others. We have discovered that our method for depositing an inorganic material on a polymer substrate works better for some polymers than it does for others. An explanation for this phenomenon may be that the precursors we used may penetrate into the fraction of the volume that is free volume, and that the polymers having relatively more free volume more readily absorb the precursors. In other words, the degree to which a polymer absorbs the precursors is related to the ability of TMA, water, or other reactant to slip between the polymer chains, and in that free volume react with the other reactant during the next half-cycle.

A porous polymer is typically described as a macroporous, mesoporous, or microporous material which looks like a sponge. As used herein, “porous” means that the material contains openings or “pores” of sufficient size that at least a gas can pass through the openings or pores. As used herein, the terms “porous, porosity,” and grammatical variations thereof, are used interchangeably with having “free volume.” As used herein, the term “nonporous” means that the material is substantially free of pores.

The inherent/intrinsic free volume in polymers seems to be due to gaps between chains where it can't pack perfectly tightly—primarily for steric reasons, but also due to temperature. As temperature increases, the free volume of polymers generally increases, based on the coefficient of thermal expansion (CTE). For example, at the glass transition temperature (Tg) of an amorphous polymer, the free volume is typically around 2.5 percent. The Tg is the temperature region where the polymer transitions from a hard, glassy material to a soft, rubbery material. Our typical ALD coating conditions are above the Tg of most polymers that we've coated, but it most likely doesn't matter if the temperature is above or below the Tg.

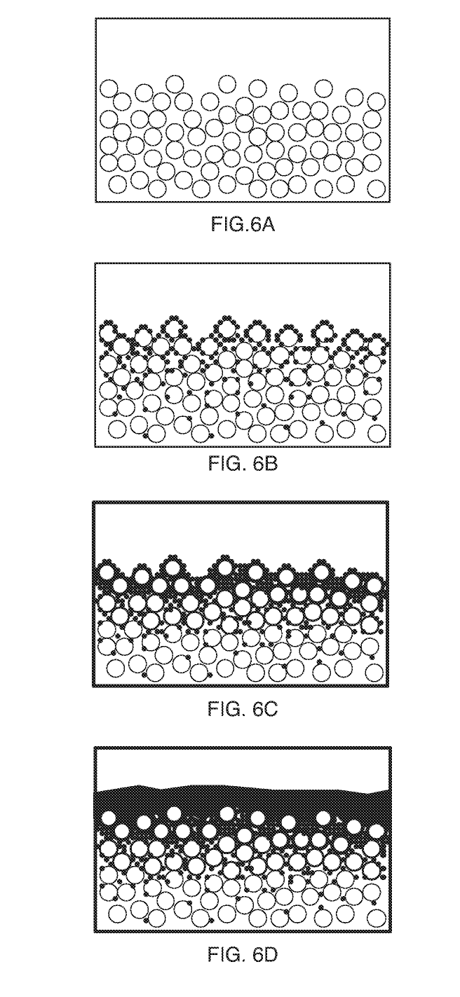

A model for r ALD on polymers having free volume or a porous surface is schematically shown in FIG. 6 and described in more detail below.

Although all polymers have some free volume, and may therefore be potentially useful as substrates upon which inorganic deposits may be formed by ALD according to the disclosed method, the following polymers, and derivatives thereof, may be particularly useful as substrates for an inorganic material deposited by our disclosed ALD method: polyethylene, polypropylene, polystyrene, polymethyl methacrylate, polybutylene, poly(naphthalene),a polymer of a conjugated diene, polyethylene terephthalate, organosilicone polymer. polycarbonates, poly(styrene-divinylbenzene) (PS-DVB), polyamides, ethylene-butene copolymers, ethylene-hexene copolymers, ethylene-methacrylate copolymers, polyethylene glycol, bis-phenol A, lyotropic liquid crystal (LLC) polymer, organic polymer particles held together by a polymer binder, and the “ultrapermeable polymer,” poly(1-trimethylsilyl-1-propyne).

As the term is used herein, a derivative of a polymer is a compound that has been formed, or can be imagined to arise, from the parent polymer compound by replacement of one atom with another atom or group of atoms.

For example, a polymer substrate useful in a composition according to an embodiment of the invention can comprise a derivative of polyethylene, polypropylene, polymethyl methacrylate, polystyrene, polycarbonate, poly(1-trimethylsilyl propene), poly(4,4′-oxydiphenylene-pyromellitimide), and combinations thereof.

In yet other embodiments, the substrate of the disclosed compositions may comprise at least one of ethylene homopolymers, and propylene homopolymers,

Also disclosed herein are compositions wherein the polymer substrate comprises at least one of polyvinylidene fluoride, polysulfones, polyether sulfones, polyesters, polyacetals, polyamides, polyimides, polyether ether ketones, polyphenylene oxides, polyphenylene sulfides, polyethylene naphthalates, and a mixture of inorganic particles with a binder polymer.

The substrate polymer may be thermoplastic or thermosetting, crosslinked or non-crosslinked, and if not crosslinked, linear or branched. In one embodiment, the inorganic film layer comprising a metal oxide is deposited by atomic layer deposition. The atomic layer deposition may be carried out in a fluidized bed reactor.

Further, the substrate polymer may exist in any physical form at the time the inorganic material is deposited, provided that the temperature is such that the substrate polymer is a solid. For example, the substrate polymer may be a particulate material having any desirable particle size, such as, for example, from about 0.001 micron, preferably from about 0.05 micron and more preferably from about 1 micron, to 1 millimeter or more, especially to about 200 microns and more preferably to about 50 to 200 microns. Preferred particulate polymers have surface areas in the range of about 0.1 to 200 m²/g or more.

Polymer films are substrates of particular interest, such as monolayer or multilayer films, that may be prepared by coextrusion processes, for example, and having a thickness of from about 0.0005 inch to about 0.010 inch. Polymer sheets having thicknesses of 0.010 inch or more are useful substrates as well. Molded articles of all types (made by any applicable molding process, such as extrusion, compression molding, vacuum forming, thermoforming, injection molding, and the like) may be used as substrates.

The chemical composition of the substrate polymer may vary widely. Substrate polymers that contain functional groups such as halogen, hydroxyl, carbonyl, carboxylic acid, primary amine, secondary amine and the like are useful, as these functional groups provide sites at which it is possible to form chemical bonds between the polymer and the inorganic material. Examples of polymers having such functional groups are polyurethanes; polyesters (aliphatic and/or aromatic, including polyethylene terephthalate), epoxy resins, epoxy-novalac resins, phenolic resins, cellulose ethers and esters (such as hydroxyethyl cellulose, hydroxypropyl cellulose, methyl cellulose, methyl hydroxylpropyl cellulose, and the like), polyvinyl alcohol, polyvinyl chloride, polyamides (such as the various nylons), polyamines, polyvinylidene chloride, halogenated or aminated poly(alkenyl aromatic) polymers, polyacrylic acid, polyacrylates, especially polymers or copolymers of an hydroxyalkyl ester of acrylic or methacrylic acid; polyacrylamide; polyimides, polycarbonates and the like. In the cases of certain thermosetting resins such as phenolic, epoxy and epoxy-novalac resins, a solid B-staged resin can be used as the substrate, as well as the fully cured resin. If polymers having functional groups are porous or have substantial free volume, the disclosed method may in sonic cases be used to deposit an inorganic film on such a polymer substrate without reacting with the functional group.

However, polymers that do not contain such functional groups are also useful as substrates. Among polymers of this type are the polyolefins, such as low density polyethylene, linear low density polyethylene, substantially linear polyethylene, high density polyethylene, polypropylene, polybutylene, and various copolymers of monoalkenes; poly(alkenyl aromatic) polymers such as polystyrene and poly(naphthalene); polymers of conjugated dienes such as polybutadiene, isoprene, and the like; PTFE, as well as block and/or random copolymers of any of the foregoing. Organosilicone polymers are likewise useful.

It is possible in some instances to perform a precursor reaction to introduce desirable functional groups onto the surface of the polymer substrate. Depending on the particular polymer, techniques such as water plasma treatment, ozone treatment, ammonia treatment and hydrogen treatment are among the useful methods of introducing functional groups.

The polymer substrate should be treated before initiating the reaction sequence to remove volatile materials that may be absorbed onto the surface. This is readily done by exposing the substrate to elevated temperatures and/or vacuum. The polymer substrate is then sequentially contacted with gaseous reactants. The reactions are performed at a temperature below that at which the organic polymer degrades, melts, or softens enough to lose its physical shape. Many polymers degrade, melt or soften at moderately elevated (e.g., 400-550K) temperatures. The temperature at which the ALD reactions are conducted is therefore generally below 550K, and preferably below 400K, more preferably below about 373K, and especially below 350K, with the upper temperature limit being dependent on the particular organic polymer to be coated. The reactants are gasses at the temperature the reactions are conducted. Particularly preferred reactants have vapor pressures of at least 10 torr or greater at a temperature of 300K. In addition, the reactants are selected such that they can engage in the reactions that form the inorganic material at the temperatures stated above. Catalysts may be used to promote the reactions at the required temperatures.

At close to the softening temperature, the chains in the polymer are in thermal agitation and mobile. Pyrolysis of the polymer begins to degrade the polymer by desorbing monomers from the polymer. This loss of monomers exposes free radical carbon chains close to the surface of the polymer. The thermal motion of the polymer chains and desorption of monomer units from the polymer is believed to provide functional groups on the surface of the polymer of reaction with the ALD reactants. Further, adsorption of the ALD reactants is believed to be facilitated by the polymer chain mobility. Thus, conducting the ALD reaction sequences at elevated temperatures close to but below the softening temperature of the polymer substrate is desirable in some instances.

The polymer substrate is generally held in a chamber that can be evacuated to low pressures. Each reactant is introduced sequentially into the reaction zone, typically together with an inert carrier gas. Before the next reactant is introduced, the reaction by-products and unreacted reagents are removed. This can be done, for example, by subjecting the substrate to a high vacuum, such as about 10-5 torr or lower, after each reaction step. Another method of accomplishing this, which is more readily applicable for industrial application, is to sweep the substrate with an inert purge gas between the reaction steps. This purge gas can also act as a carrier for the reagents. The next reactant is then introduced, where it reacts at the surface of the substrate. After removing excess reagents and reaction by-products, as before, the reaction sequence can be repeated as needed to build inorganic deposits of the desired size or thickness.

General methods for conducting ALD processes are described, for example, in J. W. Klaus et al., “Atomic Layer Controlled Growth of SiO₂ Films Using Binary Reaction Sequence Chemistry”, Appl. Phys. Lett. 70, 1092 (1997) and O. Sheh et al., “Atomic Layer Growth of SiO₂ on Si(100) and H₂O using a Binary Reaction Sequence”, Surface Science 334, 135 (1995).

A convenient method for depositing the inorganic material onto a particulate polymer substrate is to form a fluidized bed of the particles, and then pass the various reagents in turn through the fluidized bed under reaction conditions. Methods of fluidizing particulate materials are well known, and generally include supporting the particles on a porous plate or screen. A fluidizing gas is passed upwardly through the plate or screen, lifting the particles somewhat and expanding the volume of the bed. With appropriate expansion, the particles behave much as a fluid. The reagents can be introduced into the bed for reaction with the surface of the particles. In this invention, the fluidizing gas also can act as an inert purge gas for removing unreacted reagents and volatile or gaseous reaction products and as a carrier for the reagents. In the case of fluidizing extremely fine particles, vibration can be applied to assist in the fluidization process. Vibrational forces are beneficial to overcome inter-particle van der Waals forces that tend to prevent fluidization and promote a plug flow of particles in the bed. Ultra-fine, in particular, submicron and small micron sized-particles tend to form particle agglomerates that maintain fluidization in the bed and are not carried out with the outflowing gas. Applying vibrational forces allows each primary particle in the bed to be coated individually instead of merely coating the agglomerate.

Another method for depositing the inorganic material onto a particulate polymer substrate is through the use of a rotary tube reactor. The rotary tube reactor comprises a hollow tube that contains the particulate polymer. The tube reactor is held at an angle to the horizontal, and the particulate polymer passes through the tube through gravitational action. The tube angle determines the flow rate of the particulate through the tube. The tube is rotated in order to distribute individual particles evenly and expose all particles to the reactants. The tube reactor design permits the particulate polymer to flow in a near plug-flow condition, and is particularly suitable for continuous operations. The reactants are introduced individually and sequentially through the tube, preferentially countercurrent to the direction of the particulate polymer.

Polymer particles treated according to the invention preferably are non-agglomerated. As the term is used herein, “non-agglomerated,” means that the particles do not form significant amounts of agglomerates during the process of coating the substrate particles with the inorganic material. Particles are considered to be non-agglomerated if (a) the average particle size does not increase more than about live percent (5%), preferably not more than about two percent (2%), more preferably not more than about one percent (1%) (apart from particle size increases attributable to the coating itself) as a result of depositing the coating, or (b) if no more than 2 weight percent, preferably no more than 1 weight % of the particles become agglomerated during the process of depositing the inorganic material.

Because the reaction precursors are all in the gas phase, the ALD process is not a “line-of-sight” method of depositing the multiple bilayers. Instead, the reactants can cover all surfaces of the substrate, even if those surfaces are not in the direct path of the precursors as they are brought into the reaction chamber and removed. Further, because, after the nucleation phase and formation of the diffusion barrier, the reactions are self-limiting, and the precursors form only monolayer deposits on the substrate surface during each exposure, the resulting deposit that is applied per reaction cycle is highly uniform in thickness. The disclosed method permits the formation of high quality deposits on surfaces of substrates that have a wide range of geometries.

The selection of reactants is important in obtaining good adhesion of the inorganic material. At least one of the reactants is preferably one that which, if contacted in bulk with the polymer substrate, will wet the surface of the polymer substrate (a ‘wetting’ reactant). If the polymer substrate contains functional groups, the first reactant may also be reactive with those functional groups at the reaction temperatures described before, thereby forming a surface species that is chemically bonded to the polymer and capable of engaging in further reactions to form the inorganic material.

Although the invention is not limited to any theory, it is believed that a wetting reactant will absorb into the surface of the polymer substrate when applied under ALD conditions. The wetting reactant tends to penetrate somewhat beneath the surface of the polymer, such as into small pores or imperfections in the polymer surface, or even between polymer chains at a molecular level. Wetting reactant molecules thus absorbed into the polymer surface to create sites at which the other reactants can attach and react to form the inorganic material. If one of the ALD reactants will absorb into the polymer surface, it is possible to conduct the ALD reaction sequence and form adherent inorganic coatings, even if one or more of the other ALD reactants does not wet the polymer surface. For example, ALD sequences that use water as a reactant can be successfully conducted even on highly non-polar substrates such as polyolefins or organosilicones, if a wetting reactant such as trimethyl aluminum (TMA) is used.

Because most polymer surfaces have small pores and imperfections, the inorganic material often is deposited discontinuously or unevenly at first, until a number of reaction cycles have been completed. In this initial, nucleation phase, the reactions are not self-limiting. However, as more reaction cycles are repeated, individual deposits of inorganic material tend to grow together and interconnect to form a continuous coating. Thus, by selection of the polymer substrate and the number of times the ALD reaction sequence is conducted, the inorganic deposits may be formed as a plurality of individual particles or a continuous or semi-continuous film. It is believed, again without limiting the invention to any theory, that by interconnecting individual deposits of inorganic material that are formed in the first few reaction cycles, the inorganic material forms “bridges” between these deposits. These “bridges” can mechanically interlock with the polymer substrate (at a molecular or larger scale) and secure the inorganic deposits to the substrate in that manner. This mechanical interlocking may be supplemented by chemical bonding in cases where the polymer has functional groups that can form bonds to one or more of the ALD reactants. This effect is illustrated in Examples 2-4 below, in which large reactant uptakes are seen during early reaction cycles, followed by smaller uptakes during later reaction cycles as a continuous inorganic film or diffusion barrier is formed, and the reactants can no longer penetrate into pores in the polymer substrate.

Trimethylaluminum (TMA) is absorbed well into a wide variety of polymer substrates, including nonpolar polymers such as polyolefins, poly (alkenyl aromatics) and organo silicone polymers. As such, an ALD process using TMA as a reactant is particularly suitable for depositing inorganic materials onto a wide range of organic polymers. TMA ALD reactions usually form alumina (Al₂O₃); an illustrative example of an overall reaction of this type is 2Al(CH₃)₃+3H₂O→Al₂O₃+6CH₄. In the ALD process, this reaction is conducted as half-reactions as follows (following initial introduction of TMA onto the polymer surface):

Al—(CH₃)*+H₂O→Al—OH*+CH₄ (A1)

Al—OH*+Al(CH₃)₃→Al—O—Al(CH₃)₂*+CH₄ (B1)

The asterisk (*) indicates a species at the surface of the inorganic material. This particular sequence of reactions to deposit alumina is particularly preferred, as the reactions can proceed at temperature below 350K. This particular reaction sequence tends to deposit Al₂O₃ at a rate of ˜1.2 Å per AB cycle. On polymer substrates, a greater rate of growth, believed to be the result of non-self-limiting reactions in the initial or nucleation stage, is often seen, especially during the first 25-50 AB reaction cycles. This is believed to be due to the penetration of the TMA into the polymer substrate and formation of discontinuous Al₂O₃ deposits during the initial reaction cycles. Triethyl aluminum (TEA) can also be used in place of TMA in the reaction sequence.

Many ALD reaction sequences do not include a good wetting reactant. It is still possible in such cases to deposit the desired inorganic material onto the polymer substrate. One way of accomplishing this is to deposit a “precursor” inorganic material onto the substrate, via an ALD reaction sequence that includes a good wetting reactant. Reactive species on the precursor inorganic material can become reactive sites at which a second ALD sequence can be initiated to deposit the desired inorganic material. A particularly suitable “precursor” inorganic material is alumina, which is preferably deposited using reaction sequence A1/B1 above. As few as two repetitions of a reaction cycle forming a “precursor” inorganic material can be used. A preferred number of reaction cycles to deposit a “precursor” inorganic material is from 2 to about 200 cycles, especially from about 5 to about 25 reaction cycles.

Examples of binary reaction sequences for producing metal layers are described in copending application Ser. No. 09/523,491 entitled “A Solid Material Comprising a Thin Metal Film on its Surface and Methods for Producing the Same”, now U.S. Pat. No. 6,958,174, issued Oct. 25, 2005. A specific reaction scheme described therein involves sequential reactions of a substrate surface with a metal halide followed by a metal halide reducing agent. The metal of the metal halide is preferably a transition metal or a semimetallic element, including tungsten, rhenium, molybdenum, antimony, selenium, tellurium, platinum, ruthenium and iridium. The halide is preferably fluoride. The reducing agent is suitably a silylating agent such as silane, disilane, trisilane and mixtures thereof. Other suitable reducing agents are boron hydrides such as diborane.

For depositing a tungsten coating, for instance, the overall reaction, WF₆+Si₂H₆→W+2SiF₃H+2H₂, can be split into a sequence of reactions represented as follows. As neither of the reactants is a good wetting reactant, an alumina adhesion layer can be formed first as described above. The alumina layer will contain AlOH surface species that form sites to initiate the tungsten-forming reactions:

Al—OH* (substrate surface)+Si₂H₆→Al—O—SiH₃*+SiH₄

Al—O—SiH₃*+WF₆→Al—O—WF₅*+SiFH₃ (precursor reactions)

Al—O—WF₅*+Si₂H₆→Al—O—W—SiF₂H*+SiF₃H+2H₂ (A2)

Al—O—W—SiF₂H*+WF₆→Al—O—W—WF₅+SiF₃H (B2)

The asterisk (*) indicates the species that resides at the surface of the substrate or applied film. Once the precursor reaction is completed, reactions A2 and B2 are alternatively performed until a tungsten layer of desired thickness is formed.

Another binary reaction scheme suitable for depositing a metal (M²) film on an alumina adhesion layer can be represented as:

Al*—O—H (substrate surface)+M²Xₙ→Al—O—M²*Xₙ₋₁+HX (precursor reaction)

Al—O-M₂X*+H₂→Al—O-M²-H*+HX (A3)

Al—O-M²-H*+M²(acac)→Al—O-M²-M²*(acac)+H(acac) (B3)

“Acac” refers to acetylacetonate ligand, and X is a displaceable nucleophilic group. Also as before, the asterisk (*) refers to the species residing at the surface. By heating to a sufficient temperature, hydrogen bonded to the surface as M²-H will thermally desorb from the surface as H₂, thereby generating a final surface comprising M² atoms. Cobalt, iron and nickel are preferred metals for coating according to reaction sequence A3/B3.

Oxide layers can be prepared on an underlying substrate or layer having surface hydroxyl or amine groups using a binary (AB) reaction sequence as follows. In the sequences below, R represents an atom on the surface of the polymer substrate. In the case where an alumina or other adhesion layer is used, R represents a metal atom (aluminum in the case where the adhesion layers is alumina). If no adhesion layer is used, R represents an atom on the polymer. The asterisk (*) indicates the atom that resides at the surface, and Z represents oxygen or nitrogen (oxygen in the case where an alumina adhesion layer is used). M¹ is an atom of the metal (or semimetal such as silicon), particularly one having a valence of 3 or 4, and X is a displaceable nucleophilic group. The reactions shown below are not balanced, and are only intended to show the reactions at the surface of the particles (i.e., not inter- or intralayer reactions).

R—Z—H*+M¹Xₙ→R—Z-M¹Xₙ₋₁*+HX (A4)

R—Z-M¹X*+H₂O→R—Z-M¹OH*+HX (B4)

In reaction A4, reagent M¹Xₙ reacts with the R*—Z—H groups on the surface to create a new surface group having the form -M¹Xₙ₋₁. M¹ is bonded through one or more Z (nitrogen or oxygen) atoms. The -M¹Xₙ₋₁ group represents a site that can react with water in reaction B4 to regenerate one or more hydroxyl groups. The hydroxyl groups formed in reaction B4 can serve as functional groups through which reactions A4 and B4 can be repeated, each time adding a new layer of M¹ atoms. Note that in some cases (such as, e.g., when M¹ is silicon, zirconium, titanium, boron or aluminum) hydroxyl groups can be eliminated as water, forming M¹-O-M¹ bonds within or between layers. This condensation reaction can be promoted if desired by, for example, annealing at elevated temperatures and/or reduced pressures.

Binary reactions of the general type described by equations A4 and B4, where M¹ is silicon, are described more fully in J. W. Klaus et al., and O. Sheh et al., Supra. Binary reactions of the general type described by equations A4 and B4, where M¹ is aluminum, are described in A. C. Dillon el al., “Surface Chemistry of Al₂O₃ Deposition using Al(CH₃)₃ and H₂O in a Binary reaction Sequence,” Surface Science 322, 230 (1995), and A. W. Ott et al., “Al₂O₃ Thin Film Growth on Si(100) Using Binary Reaction Sequence Chemistry,” Thin Solid Films 292, 135 (1997). General conditions for these reactions as described therein can be adapted to construct SiO₂ and Al₂O₃ coatings on particulate materials in accordance with this invention. Analogous reactions for the deposition of other metal oxides such as, TiO₂ and B₂O₃ are described in Tsapatsis et al. (1991) Ind. Eng. Chem. Res. 30:2152-2159 and Lin et al., (1992), AlChE Journal 38:445-454.

Other reaction sequences can be performed to produce nitride and sulfide coatings. An illustrative reaction sequence for producing a nitride coating is:

R—Z—H*+M¹Xₙ→R—Z-M¹Xₙ₋₁*+HX (A5)

R—Z-M¹X*+NH₃→R—Z-M¹NH₂*+HX (B5)

Ammonia can be eliminated to form M¹-N-M¹ bonds within or between layers. This reaction can be promoted if desired by, for example, annealing at elevated temperatures and/or reduced pressures.

An illustrative reaction sequence for producing a sulfide coating is:

R—Z—H*+M¹Xₙ→R—Z-M1Xₙ₋₁*+HX (A6)

R—Z-M¹X*+H₂S→R—Z-M1SH*+HX (B6)

Hydrogen sulfide can be eliminated to form M¹-S-M¹ bonds within or between layers. As before, this reaction can be promoted by annealing at elevated temperatures and/or reduced pressures.

A suitable binary reaction scheme for depositing an inorganic phosphide coating is described in Ishii et al., Crystal. Growth 180 (1997) 15.

In the foregoing reaction sequences, suitable replaceable nucleophilic groups will vary somewhat with M¹, but include, for example, fluoride, chloride, bromide, alkoxy, alkyl, acetylacetonate, and the like. Specific compounds having the structure M¹Xₙ that are of particular interest are silicon tetrachloride, tetramethylorthosilicate (Si(OCH₃)₄), tetraethyl-orthosilicate (Si(OC₂H₅)₄), trimethyl aluminum (Al(CH₃)₃), triethyl aluminum (Al(C₂H₅)₃), other trialkyl aluminum compounds, and the like.

In addition, catalyzed binary reaction techniques such as described in U.S. Pat. No. 6,090,442 are suitable for producing coatings, especially oxide, nitride or sulfide coatings, most preferably oxide coatings. Reactions of this type can be represented as follows:

R—OH+C₁→R—OH—C₁ (A7a)

R—OH—C₁+R¹-M¹-R¹→R—O-M¹-R¹+R¹—H+C₁ (A7b)

R—O-M¹-R¹+C₂→R—O-M¹-R¹—C₂ (B7a)

R—O-M¹-R¹—C₂H₂O→R—O-M¹-OH+R¹—H+C₂ (B7b)

C₁ and C₂ represent catalysts for the A7b and B7b reactions, and may be the same or different. Each R¹ represents a functional group (which may be the same or different), and M and M1 are as defined before, and can be the same or different. Reactions A7a and A7b together constitute the first part of a binary reaction sequence, and reactions B7a and B7b together constitute the second half of the binary reaction sequence. An example of such a catalyzed binary reaction sequence is:

Al—OH*(adhesion layer)+C₅H₅N→Al—OH—C₅H₅N* (A8a)

Al—OH—C₅H₅N*+SiCl₄→Al—O—SiCl₃*+C₅H₅N+HCl (A8b)

Al—O—SiCl₃*+C₅H₅N→Al—O—SiCl₃—C₅H₅N* (B8a)

Al—O—SiCl₃—C₅H₅N*+H₂O→Al—O—SiOH*+C₅H₅N+HCl (B8b)

where the asterisks (*) again denote atoms at the surface. This general method is applicable to forming various other coatings, including silica, zirconia or titania.

Several techniques are useful for monitoring the progress of the ALD reactions. For example, vibrational spectroscopic studies can be performed on high surface area silica powders using transmission Fourier transform infrared techniques. The deposited coatings can be examined using in situ spectroscopic ellipsometry. Atomic force microscopy studies can be used to characterize the roughness of the coating relative to that of the surface of the substrate. X-ray photoelectron spectroscopy and x-ray diffraction can by used to do depth-profiling and ascertain the crystallographic structure of the coating.

The inorganic deposits formed in the ALD process may take the form of individual particles or a continuous or semi-continuous film. The physical form of the deposits will depend on factors such as the physical form of the polymer substrate and the number of times the reaction sequence is repeated. It has been found that very often, the inorganic material formed in the first one or several reaction sequences tends to be deposited discontinuously. As the reaction sequences are continued, the initially discontinuous deposits will often become interconnected as further inorganic material is deposited.

In many preferred embodiments, the deposits of inorganic material form an ultrathin conformal coating. By “ultrathin”, it is meant that the thickness of the coating is up to about 100 nanometers (nm), more preferably from about 0.1 nm to about 50 nm, even more preferably from about 0.5 nm to about 35 nm, and most preferably from about 1 nm to about 20 nm. Such thicknesses provide a flexible coating that provides good vapor and gas barrier properties. By “conformal” it is meant that the thickness of the coating is relatively uniform across the surface of the particle (so that, for example, the thickest regions of the coating are no greater than 3×, preferably no greater than 1.5× the thickness of the thinnest regions), so that the surface shape of the coated substrate closely resembles that of the underlying substrate surface. Conformality is determined by methods such as transmission electron spectroscopy (TEM) that have resolution of 10 nm or below. Lower resolution techniques cannot distinguish conformal from non-conformal coatings at this scale. The desired substrate surface is also preferably coated substantially without pinholes or defects.

The applied inorganic material can impart many desirable properties to the polymer substrate, depending on the particular substrate, inorganic material and end-use application. In many instances, the inorganic material forms a continuous film on the surface of the polymer substrate. This continuous film can form a barrier to diffusion of gasses and vapors such as hydrocarbons, water and oxygen, through the coated polymer. When the polymer substrate is a film, the coated polymer can be readily fabricated into packaging films, bags, bottles, other types of storage containers, gloves, protective clothing, or other types of products in which barrier properties are desired. These packaging materials are particularly suitable for packaging food, medicines or other materials that are prone to dehydration or oxidative degradation. The ultrathin inorganic layers form excellent diffusion barriers because the ultrathin films are quite flexible. The ultrathin films are therefore less susceptible to forming microcracks and thus becoming more gas permeable than thicker layers applied using other methods.

The film of inorganic material may be of any thickness. Good barrier properties are seen when a continuous film of inorganic material of a thickness of about 10 nm or more, preferably from about 20 nm to about 200 nm, and more preferably from about 20 nm to about 50 nm is deposited.

Alternatively, a barrier layer of the inorganic material may be applied using the aforementioned ALD methods to a previously-fabricated bag, bottle or other type of storage container, glove or protective article of clothing. Yet another way to make these articles is to deposit the inorganic coating on polymer particles, and then fabricate a polymer film on the article itself from the coated polymer particles. Combinations of these methods can be used to create a barrier layer that is dispersed throughout the polymer and also on the surface of the fabricated article.

Another application for which barrier properties are desirable are inflatable objects such as tennis balls, other athletic equipment, balloons, pneumatic tires and the like. Elastomeric polymers such as butyl rubber can be coated with an inorganic film according to the invention to form a material suitable as a barrier layer for such inflatable objects.

The deposited inorganic material may also serve as an adhesion layer, through which other inorganic materials can be adhered to the polymer substrate. In cases where the polymer has no functional groups that react with the ALD reactants, the deposition of an inorganic material such as alumina can provide such functional groups. Subsequent ALD reactions can take advantage of the functional groups provided by the first-deposited inorganic material, reacting with them to form a strong cohesive bond.

An example of such an embodiment is the deposition of a diffusion barrier layer such as TiN or TaN on low k dielectric polymers. Semiconductor devices often use aluminum alloy interconnects insulated with SiO₂ dielectric layers. As semiconductor devices are fabricated with smaller dimensions, the resistance capacitance (RC) time constant of the interconnects eventually limits the device speed. One strategy for reducing the RC time constant is to replace the aluminum with copper.

Further improvements in device performance are achieved by reducing the capacitance of the dielectric volume between the interconnect lines. This may be accomplished by changing from SiO₂ to a lower dielectric constant material (a “low-k” material). Organic polymers are being considered as low-k materials. A problem with using organic polymers as low-k materials is copper diffusion. Copper atoms can migrate from the interconnects through the organic polymer at high temperatures in the presence of electric fields and cause device failure. Diffusion barrier materials such as TiN may be deposited on the organic polymer prior to the copper deposition to prevent copper diffusion. The diffusion barrier material should be continuous and preferably is conformal to ensure a uniform coating.

The deposited inorganic material may provide an electrical insulating or conducting layer on the polymer substrate. Conducting polymers are used in a variety of electronic applications, such as organic light emitting diodes (OLEDs). These conducting polymers often need to be isolated from other conducting layers. OLED devices in particular need insulating layers to define proper device performance. A deposited film of inorganic material such as Al₂O₃ form an insulating layer on such conducting polymers. A deposited Al₂O₃ layer sandwiched between conducting polymer layers can provide a means for fabricating electron tunneling devices such as electroluminescent displays. The polymer substrate allows the display to be flexible.

An Al₂O₃/ZnO mixture can be used to define conducting layers with variable resistivity. The Al₂O₃/ZnO alloy system spans a full 18 orders of magnitude in resistivity, and so, if deposited on a nonconductive polymer substrate in accordance with this invention, it is possible to provide conducting layers of controllable conductivity onto a polymer substrate.

The deposited inorganic material may also improve some desired mechanical property of the polymer, such as impact strength, tensile strength and the like. The inorganic film can also provide corrosion resistance to the polymer substrate.

Polymer particles according to the invention may be formed into a dispersion in an aqueous and/or organic liquid phase for making coatings for a wide range of coating applications.

The deposited inorganic material in many cases can serve as a protective coating for the polymer substrate. For example, the coating in many cases imparts ultraviolet, chemical, or erosion barrier properties to the coated polymer. These barrier properties can improve or extend the useful life of polymers that are used as structural components in a wide variety of appliance, vehicle or construction applications, for example. The inorganic material may be deposited on molded parts made from a variety of structural and engineering polymers, or may be deposited onto polymer sheets or particles that are subsequently shaped to form the structural components.

Polymer particles made according to the invention are useful for making nanocomposites and/or organic/inorganic alloys. One way of making the nanocomposites is to melt process the coated particles. “Melt processing” involves any method by which the particles are melted together to form a molten mass, such as, for example, any extrusion or melt spinning or molding process. The molten mass may be formed directly into some desired article, or may be extruded and formed into pellets or particles for later fabrication. The melt processing intimately mixes the inorganic material into the polymer in the form of nano-scale particles. The melt-processed polymer may then be fabricated in any suitable manner to form a structural component for appliance, vehicle or construction applications, among others. The resulting nanocomposite will in most cases have higher impact strength than the neat polymer substrate. This method of forming nanocomposites overcomes many of the difficulties seen with conventional methods of making nanocomposites, because it is no longer necessary to defoliate the reinforcing material and disperse it into the polymer.

In other cases, the nano-dispersed particles can provide improved flame retardancy to the polymer. In particular, polymer particles according to the invention that have a deposited metal coating can be extruded to form a nanocomposite which, if combined with phosphorous-containing flame retarding compounds, have decreased polymer flammability and increased charring on fire testing. Oxide coatings applied to polymer particles according to the invention can result in similarly increased charring upon fire testing, with or without additional flame retardant.

In another application, the polymer particles coated according to the invention can be used to encapsulate electronic parts. Of particular interest are solid epoxy resins that are coated with alumina. The alumina layer enhances the compatibility of the polymer particles with various fillers such as AlN, BN or Si₃N₄. It is further possible to apply a coating of these nitrides to the polymer particles themselves (preferably using an alumina adhesion layer).

In yet another application, an active catalyst can be deposited onto the coated polymer particles of the invention to form a supported catalyst with the polymer particles as the support. Particularly suitable polymers for this purpose are crosslinked materials, in particular crosslinked polystyrene polymers as are used in gel- and/or macroporous-type ion exchange resins. The crosslinked polymers may contain functional groups (such as primary or secondary amino, carboxyl or sulfonate groups) that serve as initiation points for the deposition of the inorganic material. Several embodiments of the invention are useful in this application. In one embodiment, the catalytic material, which is typically a metal such as platinum, palladium, cobalt, zinc, magnesium, tungsten, and the like, is deposited onto the polymer substrate using ALD methods as described herein. An alumina, silica or other adhesion layer is preferred because metals tend to bind to alumina and silica surfaces well. The adhesion layer thus promotes the loading of the polymer particles with the metallic catalyst. Since atomic layer deposition is not line-of-sight dependent, it is possible for the coatings to be placed along the inner walls of pores within the catalyst particles. In other embodiments, an adhesion layer is deposited onto the polymer substrate as described before, and the catalytic material is deposited onto the coated polymer particles using some other technique. A chemical reaction is then conducted in the presence of particles coated with a metal that is a catalyst for the reaction. An example of such a reaction is a gas phase polymerization.

The inorganic material in many cases alters the surface properties of the polymer substrates without altering their bulk properties. For example, the coatings sometimes passivate reactive polymer surfaces and provide a barrier to protect the bulk materials or the contents within the bulk materials from the surrounding environment. If the coatings are placed on polymer particles, prior to fabricating components from the particles, it is possible for the coatings to be intimately blended in the polymer matrix and improve the properties of the fabricated component. Rather than strictly improved chemical effects, it is also possible for the coatings to provide desirable physical or structural property that the bulk material does not possess.

Polymer particles according to the invention can also be used to form coatings in flame spraying and other processes. Particles having TiO₂ coatings may act as photo-initiated catalysts to oxidize dirt deposits and provide a self-cleaning coating. Such particles may be used as a paint additive for that purpose. Particles having a metal coating can provide metallic and/or pearlescent effects for metallic finishes, and can be used as additives in paint formulations for that purpose. Particles having a variety of inorganic coatings can be used as additives for improving scratch and wear resistance in paints and coatings.

Coatings of particular interest are so-called “solventless” or “powder” coatings. In powder coating applications, a dry, particulate powder is applied to some substrate that is to be coated, and the applied powder is then melted to coalesce the particles into a smooth film. Specific applications include coating for wood furniture, prefinished wood floors, coatings for optical fibers, vinyl flooring covers, metal coatings (such as automobile exterior body parts), and glass coatings. Both thermoset and thermoplastic types are used, including polyurethanes, epoxies, polyesters, melamine-vinyl ether resins, and the like. In some cases, the film then undergoes a curing step, in which a chemical curing agent or energy (typically a source of heat or UV light) is applied in order to complete the curing of the film. Melting and/or curing is typically done at temperatures of 350-400° F., but due to safety and handling considerations, it is desirable to reduce those temperatures into the range of 250-300° F. It has been found that lower-curing powder coating materials tend to agglomerate when stored, even at ordinary room temperatures. This problem of low-temperature agglomeration is overcome using this invention. A continuous coating of an inorganic material, applied as described herein, effectively prevents the polymer particles from adhering to each other at low temperatures. Because the inorganic coating is extremely thin, it still allows the particles to melt together at higher temperatures to form a good quality film. In many cases where an inorganic pigment (such as TiO₂) is used in the coating formulation, the inorganic coating can double as a pigment, reducing or even eliminating the need for additional pigments to be added to the coating formulation.

In yet another application, a polymer film is coated with an alumina or other adhesion layer, and a titanium nitride or tantalum nitride layer is deposited, using ALD or other methods, onto the adhesion layer. The resulting structure is a useful polymer substrate for plastic microelectronic packaging. The titanium or tantalum nitride layer functions as a copper diffusion barrier. The inorganic layer may also facilitate the etching of metals more easily than could be achieved directly on the polymer surface. Other forms of microelectronic packaging can be made by depositing other inorganics onto a polymer film, with or without an adhesion layer.

The following examples are provided to illustrate the invention, and are not intended to limit the scope thereof. All parts and percentages are by weight unless otherwise indicated.

### PART I EXPERIMENTS

### Examples 1-5

### Example 1

Low density polyethylene particles (LDPE) with a diameter of ˜2 microns were mounted in a tungsten screen and positioned in a vacuum chamber designed for Fourier transform infrared (FTIR) experiments. The temperature of the LDPE particles was controlled by resistive heating of the tungsten screen.

The Al₂O₃ ALD was performed at 350 K, using the reaction sequence A1/B1 described above. FTIR was used to monitor the progress of the reactions. Prior to beginning the reaction sequence, the FTIR spectra of the LDPE particles exhibited prominent C—H stretching vibrations at 2960-2840 cm⁻¹ and the C—C stretching vibrations at 1465 cm⁻¹. Additional vibrational features attributed to the polyethylene hydrocarbon chains were observed at 720, 1110, 1300, and 1375 cm⁻¹. The LDPE particles were first exposed to H₂O at 350 K. Because of the hydrophobic nature of the LDPE particles, no vibrational features associated with H₂O, in particular the O—H vibrational stretching features, were observed by FTIR following the initial H₂O exposure.

The LDPE particle was then exposed to the TMA reactant at 350 K. The FTIR difference spectrum revealed new vibrations at ˜2900 cm⁻¹ that are assigned to the C—H stretching vibrations from the CH₃ species derived from TMA. The FTIR data confirmed that TMA either absorbs into the polyethylene, adsorbs on the polyethylene particles, or reacts with species on the polyethylene surface. (From later studies, we concluded that the TMA absorbs into the porous polymer or diffuses into the free volume of the polymer.) When the particles were then exposed to water, the FTIR difference spectrum exhibited a new vibrational feature at 2900-3600 cm⁻¹ attributed to O—H stretching vibrations. In addition, the C—H stretching vibrations at ˜2900 cm⁻¹ that were added by TMA were removed by the H₂O reaction. The FTIR spectrum confirmed that water has reacted with the TMA at the particle surface.

As the TMA/H₂O cycles were continued, the growth of an Al₂O₃ bulk vibrational feature began to appear at 500-950 cm⁻¹. This feature grew progressively as the reaction cycles were repeated, establishing that Al₂O₃ was being deposited on the LDPE particles.

Further confirmation of the deposition of an Al₂O₃ film on the LDPE particles was provided by transmission electron microscopy (TEM) images of the Al₂O₃-coated LDPE particles. TEM images recorded after 40 reaction cycles at 350 K indicated an Al₂O₃ film of between 150-200 Å was produced. This thickness was greater than expected after 40 AB cycles. This thicker Al₂O₃ film is attributed to the diffuse nature of the LDPE surface and near surface region. TMA is believed to have diffused into the free volume of the polymer chain network near the surface of the LDPE particle. There may be present some carbon radicals that were produced by a side reaction, but any reaction of TMA with these radicals would have been insignificant. The diffusion of TMA into the polymer chain network caused the TMA to become distributed over a relatively wide zone in the near surface region of the LDPE polymer, and as a result, the deposited alumina film was similarly formed over this wide zone.

### Example 2

The atomic layer deposition of Al₂O₃ on polymethyl methacrylate (PMMA), polyvinylchoride (PVC), and polypropylene (PP) was performed using quartz crystal microbalance (QCM) studies. QCM methods are very sensitive to mass and can easily measure mass changes of ˜0.3 ng/cm² that correspond to the deposition of fractions of an atomic layer of Al₂O₃. By spin-coating various polymer films onto the QCM sensor, the adsorption or absorption of various chemical species can be measured accurately on polymer films. Likewise, the growth of thin films on polymer films can also be monitored with extreme precision.

The thickness of the PMMA film on the QCM sensor used in this Example is 1300 Å. The Al₂O₃ ALD was performed at 86° C. using a t₁-t₂-t₃-t₄ pulse sequence of 1-20-1-20. T₁ is the trimethylaluminum (TMA) reactant pulse; t₂ is the purge time after the TMA pulse; t₃ is the H₂O reactant pulse; and t₄ is the purge time after the H₂O pulse. All times were measured in seconds.

Mass measurements during the ALD process revealed a large mass increase during TMA reactant exposure. Subsequently, the mass decreased during the purge time after the TMA pulse. This mass decrease corresponds to the loss of some of the absorbed TMA. The mass decrease was stopped with the introduction of the H₂O reactant pulse. However, there was no obvious increase in mass corresponding with the H₂O reactant pulse, which is consistent with the replacement of —CH₃ groups with —OH groups.

The second TMA reactant pulse again led to an increase in the QCM mass. Likewise, mass was lost during the purge after the second TMA pulse. The behavior following the second H₂O reactant pulse was also similar. However, the total mass increased following the second H₂O reactant pulse. This mass increase corresponds to the growth of Al₂O₃ on the PMMA polymer film. Subsequent TMA/H₂O reactant cycles displayed similar behavior. The total mass increased following each TMA/H₂O reactant cycle, indicating the growth of the Al₂O₃ layer. The pronounced mass increases during the TMA reactant exposures indicate that the ALD reactions are not self-limiting. The mass increases were progressively reduced in magnitude during the first 20 TMA/H₂O reactant cycles. After these 20 TMA/H₂O reactant cycles, only a small mass increase occurred during the TMA reactant pulse and no pronounced mass reduction occurred during the purge following the TMA reactant pulse. This behavior suggests that the Al₂O₃ ALD film deposited during the first 15-20 TMA/H₂O reactant cycles had formed a diffusion barrier at the PMMA polymer surface that impeded the further diffusion of TMA into the polymer. Because the TMA could no longer penetrate into the polymer, it could deposit only at the surface. For that reason, TMA uptake became less as the number of reaction cycles increased. Only after about 20 TMA/H₂O reactant cycles, was the growth of the mass with number of TMA/H₂O reactant cycles essentially linear, as would be expected for self-limiting reactions typical of classical ALD. This linear mass increase with number of TMA/H₂O reactant pulses would continue indefinitely with the repetitive pulse sequence because the Al₂O₃ film has formed a diffusion barrier on the PMMA polymer surface.

### Example 3

Example 2 was repeated, this time using a polypropylene film deposited on the QCM sensor at a thickness of ˜6000 Å. The Al₂O₃ ALD was performed at 80° C., again using a t₁-t₂-t₃-t₄ pulse sequence of 1-20-1-20. Similar to the results in Example 2, the TMA reactant pulse led to a large increase in the mass recorded by the QCM. The mass decreased during the purge following the TMA reactant pulse. This behavior is again explained as the diffusion of TMA into the PP polymer during the TMA reactant pulse. Subsequently, some of the TMA diffuses out during the purge following the TMA reactant pulse. Repeating TMA and H₂O reactant pulses led to a progressive increase of mass associated with the growth of Al₂O₃. However, the magnitude of the mass increase during the TMA reactant pulses decreases versus number of TMA/H₂O reactant cycles. This decrease in magnitude is attributed to the growth of the Al₂O₃ ALD film. The Al₂O₃ ALD film serves as a diffusion barrier and impedes the diffusion of TMA into the PP polymer film. After ˜15 TMA/H₂O reactant cycles, the mass increased substantially linearly with number of TMA/H₂O reactant cycles. The mass increase during the TMA reactant pulse becomes reduced. Both of these observations are consistent with an Al₂O₃ diffusion barrier being formed during the first 15 TMA/H₂O reactant cycles. Once the Al₂O₃ ALD diffusion barrier is established on the PP polymer surface, the Al₂O₃ ALD film grows linearly as expected for Al₂O₃ ALD on a flat oxide surface.

### Example 4

Example 2 was again repeated, this time using a polyvinylchoride (PVC) polymer film. Very similar behavior was observed in comparison to Al₂O₃ ALD on PMMA and PP as shown in Examples 2 and 3. The Al₂O₃ deposition was performed at 80° C. using a t₁-t₂-t₃-t₄ pulse sequence of 1-20-1-20.

The TMA readily diffused into the PVC polymer during the TMA reactant pulse. However, in contrast to the results on PMMA and PP, the TMA did not diffuse out during the purge time after the TMA reactant pulse. This behavior indicates that TMA is more strongly absorbed by PVC than by PMMA or PP. Large amounts of TMA were absorbed during the initial TMA/H₂O reactant cycles. After approximately 15 TMA/H₂O reactant cycles, the large mass increases were no longer observed during the TMA reactant pulses. This behavior indicates that an Al₂O₃ diffusion barrier had been formed on the PVC polymer film. For additional TMA/H₂O reactant cycles, the mass increased linearly as expected for the growth of an Al₂O₃ ALD film.

### Example 5

A continuous alumina coating was applied by atomic layer deposition to a 4″ by 4″ sheet of a bisphenol-A type polycarbonate (Bayer Makrolon™ AR) having a thickness of about 6 mm (¼ inch). This polycarbonate sheet, prior to applying the alumina coating, was coated on each side with a hard UV protective coating. The precursors were trimethyl aluminum and water. 200 reaction cycles were performed at 95° C. to deposit an alumina coating approximately 25 nm thick on one planar surface of the polycarbonate sheet. To the naked eye, the resulting alumina-coated polycarbonate sheet appeared equally transparent as the uncoated starting material.

The coated polycarbonate sheet was exposed in air to 593 hours of solar radiation using a Spectrosun™ X25 Solar Simulator (Spectrolab Inc.). For comparison, an uncoated sample of the Bayer Makrolon AR sheet was similarly exposed.

The uncoated polycarbonate sheet visibly yellowed on this test. The alumina-coated polycarbonate sheet, on the other hand, showed no yellowing that was visible to the naked eye. An absorbance spectrum of the alumina-coated polycarbonate sheet was taken across the wavelength range of 375 to 2000 nm. A similar spectrum of an uncoated sample of the Makrolon AR polycarbonate sheet also was taken. Percent transmission for the two samples was very similar across the entire range of wavelengths, except that the uncoated polycarbonate sheet was observed to absorb more light in the ˜425 nm region, which is consistent with the yellow color of that sample as seen by the naked eye. The spectra further demonstrated that the presence of the 25 nm alumina coating has essentially no effect on the transparency of the polycarbonate.

### PART II EXPERIMENTS

### Examples 6-10

### Protocol Used for Examples 6-10

Each polymer film was prepared by spin-coating onto the surface of a quartz crystal microbalance (QCM) or the surface of a Si(100) wafer. Al₂O₃ ALD during the sequential trimethyl aluminum (TMA) and water (H₂O) exposures was monitored in situ on each polymer using the QCM. The QCM measurements revealed distinct differences for each polymer in the initial nucleation period during Al₂O₃ ALD. Following the initial nucleation period, linear Al₂O₃ ALD growth was observed on all the polymers. The thickness of the Al₂O₃ ALD films was also characterized by ex situ surface profilometry. Based on the QCM measurements, a model is proposed for Al₂O₃ ALD nucleation and growth on polymers. This model is based on the absorption of TMA into the near-surface region of the polymer. The absorbed TMA is then available for subsequent reaction with the H₂O exposure. This model for Al₂O₃ ALD does not require specific chemical groups on the polymer surface to initiate Al₂O₃ ALD. This model should be valuable to understand and optimize the use of these Al₂O₃ ALD films as seed layers and gas diffusion barriers on polymers.

Al₂O₃ Film Growth in a Viscous Flow Reactor

The viscous flow reactor for this research consisted of a multi-port chamber with a 10 cm diameter glass view-port. Stainless steel tubes with an inside diameter of 1.4 inch led into and out of this chamber. Ultrahigh purity N₂ carrier gas flowed continuously through the stainless steel tubes at a mass flow rate of ˜35 sccm. The reactor was operated at a pressure of ˜300 mtorr with this N₂ carrier gas flow. Heating tape maintained the chamber reactor at a temperature of ˜85° C. The upstream end of the flow tube was fitted with two channels for the introduction at ˜20° C. of the chemical precursors, Al(CH₃)₃ (Trimethylaluminum (TMA)), with a 97% purity (Aldrich), and HPLC grade H₂O (Optima), into the N₂ carrier gas. The TMA and H₂O precursors were alternatively introduced into the N₂ carrier gas using pneumatic switching valves. Al₂O₃ growth was performed at 85° C. The reactant purges were long and the reactant exposure sequence was 1 s (TMA/N2)-29 s (N₂)-1 s (H₂O/N₂)-29 s (N₂).

The film growth was monitored with an in situ quartz crystal microbalance (QCM). QCM is a standard research technique for measuring the progress of ultrathin film growth. The sensor signal from the AT-cut quartz crystal at 6 MHz was measured with a Maxtek TM400 film thickness monitor. The resolution of the QCM measurements was 0.4 ng cm⁻². Assuming an Al₂O₃ density of 3.0 g cm⁻³, this mass sensitivity translates into a resolution for the Al₂O₃ film thickness measurements of 0.013 Å. QCM sensors were mounted in a Maxtek BSH-150 bakeable sensor head that was attached to a 2.75 inch Conflat flange. The sensor head incorporated a tube for the flow of ˜10 sccm of N₂ across the back surface of the QCM sensor to prevent thin film deposition.

### Polymer Film Preparation and Characterization

The experiments were conducted concurrently on thin polymer films spin-coated onto the QCM crystal sensors and the Si(100) substrates. The unpolished QCM crystal sensors were obtained from Maxtek. The polymer films were spin-coated onto the QCM crystal sensors or the silicon squares using a Laurell Technologies Model WS-400A-6NPP-Lite Single Wafer Spin Processor. For good film uniformity, solutions of 5 wt % polymer in solvent were utilized and spin-coated at 3000 rpm for 60 seconds.

The polymer solids were obtained in powder, pellet, or rubbery solid form from Scientific Polymer Products Inc. The polymers used in this work were: polyethylene (CAS No. 9002-88-4; PPE #536) MW ˜1,100 dissolved in decalin; polystyrene (CAS No. 9003-53-6; PS #846) MW ˜190,000 dissolved in toluene; polypropylene atactic (CAS No. 9003-07-0; PP #783) MW ˜10,000 dissolved in toluene; and polyvinylchloride (CAS No. 9002-86-2; PVC #645) MW ˜90,000 dissolved in cyclohexanone.

Immediately prior to spin-coating, the polymer solutions were heated to ˜50° C. The polyethylene solution required heating to ˜90-100° C. to fully dissolve the polymer by breaking up the clusters of solid polymer that are common at room temperature. The spin processor environment and all substrates were at room temperature during the spinning process.

### RESULTS FOR EXPERIMENTS

### Examples 6-10

### Example 6—Polystyrene (PS)

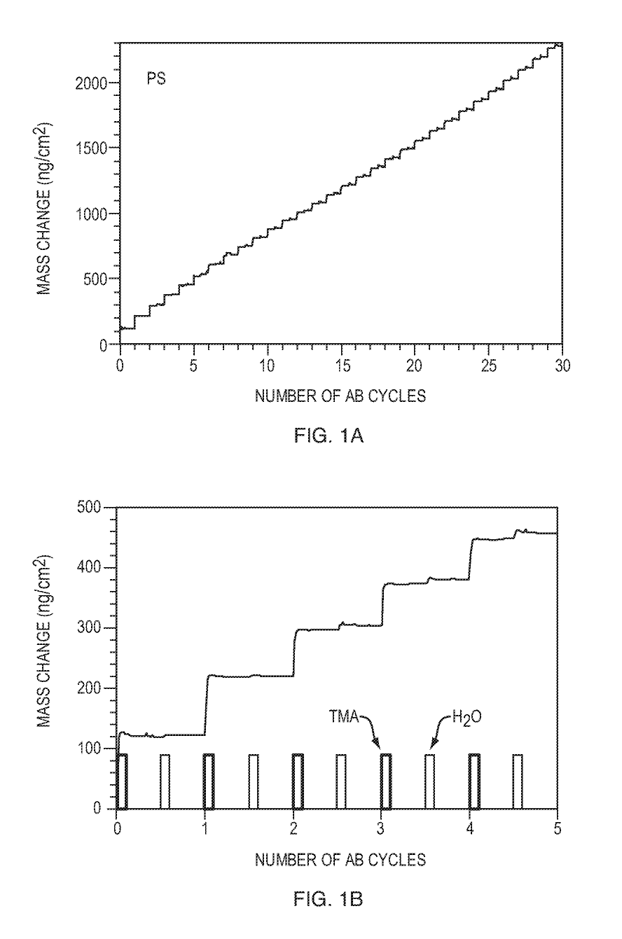

FIG. 1A shows the results for Al₂O₃ ALD on PS at 85° C. at higher mass resolution during the first 30 AB cycles. A total mass change of ˜2300 ng cm⁻² is observed after the 30 AB cycles. The Al₂O₃ ALD growth is not strictly linear over these first 30 AB cycles. The mass deposited during each AB cycle decreases slightly after the first 10-15 AB cycles. The structure of the mass changes versus TMA and H₂O exposures reveals distinct steps that are characteristic of Al₂O₃. In addition, the mass change transients during the TMA and H₂O exposures also evolve during the first 10-15 AB cycles.

FIG. 1B shows the mass changes at even higher mass resolution for the first 5 AB cycles. A large mass change of ˜120 ng cm⁻² is observed during the first TMA exposure on PS at 85° C. The TMA and H₂O exposure sequence coinciding with the mass changes is also given for comparison. The TMA exposure occurs at whole-integer number of AB cycles. The H₂O exposure occurs at the half-integer number of AB cycles. The mass change of ˜120 ng cm⁻² is directly correlated with the TMA exposure. Only a small fraction of the TMA desorbs after the TMA exposure. The H₂O exposure stabilizes the mass change after the TMA exposure.

### Example 7

### Polypropylene (PP)

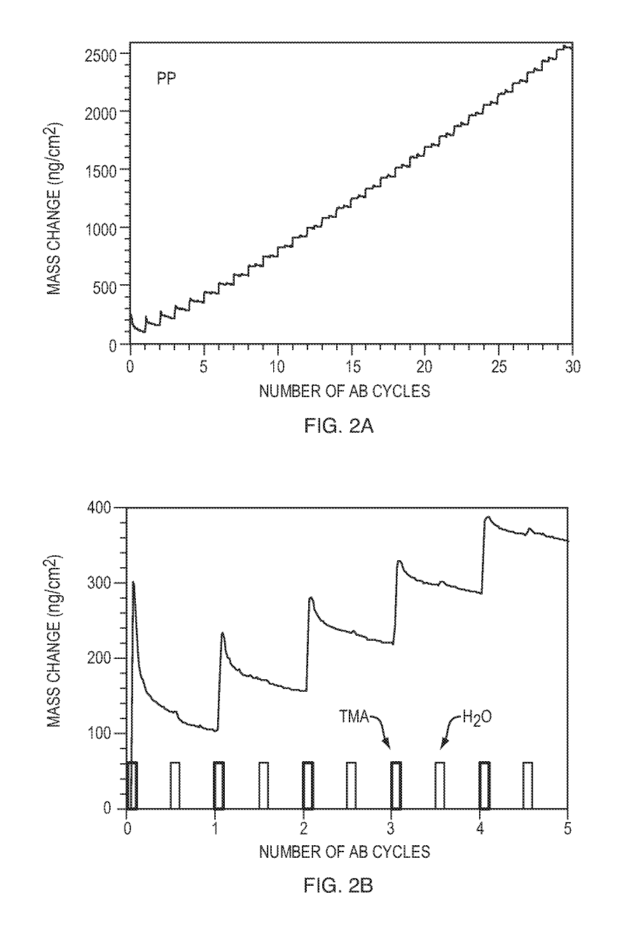

FIG. 2A shows the mass change in ng/cm² versus number of AB cycles during Al₂O₃ ALD on polypropylene (PP) at 85° C. for 30 AB cycles. Large mass transients are observed during the TMA exposures in the nucleation region. After the nucleation period. Al₂O₃ ALD displays linear growth on PP with an average growth rate of 55±22 ng/cm² per AB cycle. A total mass change of ˜2500 ng/cm² is observed in FIG. 2A after the 30 AB cycles. This total mass change is comparable to the ˜2300 ng/cm² observed in FIG. 1A after 30 AB cycles of Al₂O₃ ALD on PS.

The first 5 AB cycles during Al₂O₃ ALD on PP at 85° C. are shown at higher mass resolution in FIG. 2B. The TMA and H₂O exposure sequence coinciding with the mass changes is also displayed for comparison. The mass increase measured during the first TMA exposure is extremely large. A mass increase of ˜300 ng/cm² is observed prior to a mass decrease following the TMA exposure. This mass transient is consistent with the absorption of TMA into PP followed by the desorption of some of the TMA.

The mass change during the second TMA exposure at the AB cycle number 1 in FIG. 2B is also very large and >100 ng/cm². This mass transient decreases after the TMA exposure. This behavior is consistent with the absorption of TMA followed by some TMA desorption. The third, fourth and fifth TMA exposures also show large mass gains during the TMA exposures followed by mass decreases after the TMA exposure. However, the mass increases and decreases are smaller with increasing number of AB cycles.

### Example 8

### Polymethylmethacrylate (PMMA)

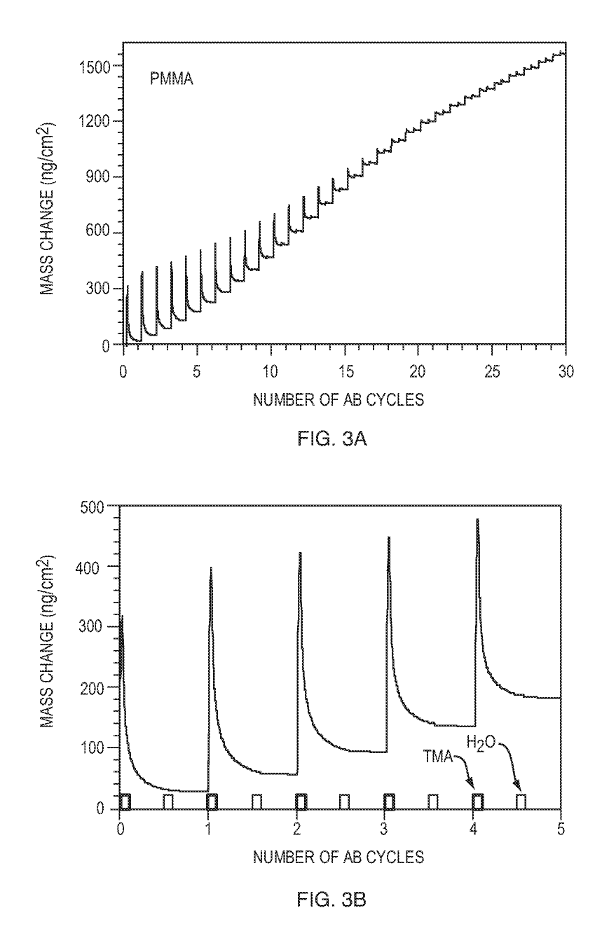

The absorption of large quantities of TMA during TMA exposures are also observed for Al₂O₃ ALD on polymethylmethacrylate (PMMA). FIG. 3A shows the mass change versus number of AB cycles during Al₂O₃ ALD on PMMA at 85° C. The QCM measures a rapid mass increase of ˜300 ng/cm² with the first exposure of TMA. The pronounced absorption of TMA during TMA exposures and desorption of TMA after the TMA exposures is dramatically evident during the first 10-15 AB cycles. Approximately 90% of the absorbed TMA mass is lost after the TMA exposure. The nucleation period for Al₂O₃ ALD occurs during the first 20 AB cycles. During this nucleation period, TMA uptake gradually decreases with increasing number of AB cycles. Subsequently, a linear Al₂O₃ ALD growth rate is reached with an average growth rate of 49±10 ng/cm² per AB cycle based on six separate experiments.

The first 5 AB cycles of Al₂O₃ ALD on PMMA at 85° C. at higher mass resolution are shown together with the TMA and H₂O exposure sequence in FIG. 3B. The pronounced uptake of TMA during TMA exposures and equally precipitous loss of TMA after the TMA exposures are vividly apparent. A steady mass increase occurs with every AB cycle. The mass change levels off with the H₂O exposure. The H₂O exposure may react with the remaining TMA in the PMMA film and stop the desorption of this TMA from the film.

### Example 9

### Polyethylene (PE)

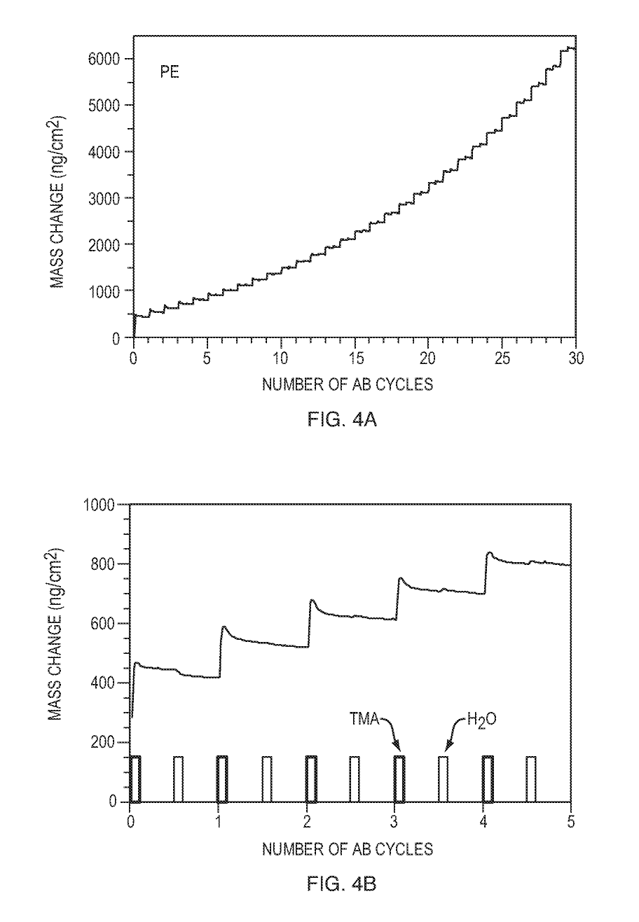

Al₂O₃ ALD on polyethylene (PE) at 85° C. is shown in FIG. 4A for the first 30 AB cycles. FIG. 4B displays the first 5 AB cycles at higher mass resolution. The QCM measures a large mass gain during the first TMA exposure of ˜450 ng cm⁻². This large TMA absorption is followed by a minimal TMA desorption. The mass change decreases to only 400 ng cm⁻². The H₂O exposure appears to stop the desorption of any remaining TMA.

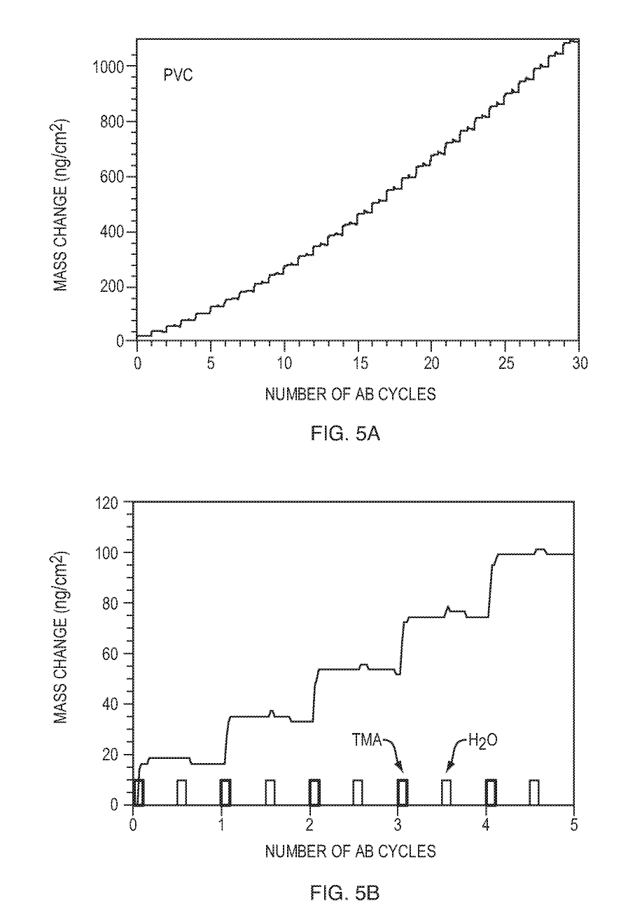

A comparison of FIG. 4B for PE and FIG. 3B for PMMA reveals the large capacity for PE to absorb TMA. The large mass gain of ˜450 ng cm⁻² during the first TMA exposures on PE is larger than the mass gain of ˜300 ng cm⁻² during the first TMA exposures on PMMA. In addition, PE has a higher retention of TMA. Subsequent TMA exposures also lead to large TMA absorption and large mass changes every AB cycle. After 30 cycles, a total mass change of ˜6200 ng cm⁻² is observed for Al₂O₃ ALD on PE. In comparison, a total mass change of ˜1500 ng cm⁻² is monitored in FIG. 5A for Al₂O₃ ALD on PMMA after 30 cycles.

### Example 10

### Polyvinylchloride (PVC)

FIG. 5 A shows the results for Al₂O₃ ALD on polyvinylchloride (PVC) films at 85° C. during the first 30 AB cycles. The absolute mass change of ˜1200 ng cm⁻² after 30 AB cycles is much less than the mass change observed for Al₂O₃ ALD on PE after 30 cycles in FIG. 4A. FIG. 5B displays the first 5 AB cycles at higher mass resolution. Mass changes of only ˜18-20 ng cm⁻² are observed for the first several TMA exposures. Although the total TMA absorbed during the TMA exposures is much smaller for PVC compared with PP, PMMA and PE, the absorbed TMA is not desorbed following the TMA exposures. The PVC retains the TMA and the measured mass change is nearly constant until the subsequent TMA exposure.

TABLE 1

| | | | ng/cm² | ng/cm² | ng/cm² |
|---|---|---|---|---|---|
| | ng/cm² mass | ng/cm² mass | mass | mass | mass |
| | increase in 1 | increase in 5 | increase in | increase in | increase in |
| Polymer | cycle | cycles | 10 cycles | 20 cycles | 30 cycles |
| Control | 44 | 222 | 445 | 890 | 1335 |
| PVC | 20 | 100 | 280 | 675 | 1200 |
| PMMA | 320 | 480 | 715 | 1190 | 1600 |
| PS | 120 | 460 | 900 | 1550 | 2300 |
| PP | 300 | 390 | 810 | 1690 | 2500 |
| PE | 460 | 825 | 1500 | 3300 | 6200 |

TABLE 1 shows the total mass deposited on the polymer (or the equivalent QCM crystal control) in the first 1, 5, 10, 20 and 30 cycles of Al₂O₃ film growth for the polymers used in this study. We saw that in the early stages of the growth which enables the film growth, the Al₂O₃ grows either faster or slower than on the quartz surface of the QCM crystal control. In some cases the growth is significantly faster.

FIG. 1A shows the mass change at higher mass resolution measured by QCM versus number of AB cycles during Al₂O₃ ALD on PS at 85° C. for 30 AB cycles. FIG. 1B shows the mass change at highest mass resolution versus number of AB cycles during Al₂O₃ ALD on PS at 85° C. for 5 AB cycles. TMA and H₂O exposure sequence coinciding with mass changes is given for comparison.

FIG. 2A shows the mass change measured by QCM versus number of AB cycles during Al₂O₃ ALD on PP at 85° C. for 30 AB cycles. FIG. 2B shows the mass change at higher mass resolution versus number of AB cycles during Al₂O₃ ALD on PP at 85° C. for 5 AB cycles. TMA and H₂O exposure sequence coinciding with mass changes is given for comparison.

FIG. 3A shows the mass change measured by QCM versus number of AB cycles during Al₂O₃ ALD on PMMA at 85° C. for 30 AB cycles. FIG. 3B shows the mass change at higher mass resolution versus number of AB cycles during Al₂O₃ ALD on PMMA at 85° C. for 5 AB cycles.

FIG. 4A shows the mass change measured by QCM versus number of AB cycles during Al₂O₃ ALD on PE at 85° C. for 30 AB cycles. FIG. 4B shows the mass change at higher mass resolution versus number of AB cycles during Al₂O₃ ALD on PE at 85° C. for 5 AB cycles.

FIG. 5A shows the mass change measured by QCM versus number of AB cycles during Al₂O₃ ALD on PVC at 85° C. for 30 AB cycles. FIG. 5B shows the mass change at higher mass resolution.

FIG. 6A through FIG. 6D depict a model for Al₂O₃ ALD on polymer films. FIG. 6A shows a cross-section of polymer film represented by loosely packed circles. FIG. 6B depicts Al₂O₃ nucleation clusters forming from H₂O reaction with TMA trapped in near surface region. FIG. 6C depicts coalescence of Al₂O₃ clusters and closure of space between polymer chains. FIG. 6D shows the resulting formation of dense Al₂O₃ film that grows on top of polymer surface.

### ANALYSIS/DISCUSSION

### Examples 6-10

### Mass Changes During Initial TMA Exposures

Distinct mass increases are observed during the initial TMA exposures on the various polymer films. These mass increases vary dramatically between the polymers. Small mass increases of ˜20 ng cm⁻² are measured during the initial TMA exposures on PVC. Intermediate mass increases of ˜120 ng cm⁻² are observed during the initial TMA exposures on PS. Large mass increases of 300, 320 and 460 ng cm⁻² are measured during the initial TMA exposures on PP, PMMA and PE, respectively. In addition, the stabilities of the TMA in the polymer films are very different. PS, PE and PVC retain most of the TMA after the TMA exposures. PP and PMMA lose most of the TMA after the TMA exposures.

The magnitude of the mass increases during the initial TMA exposures can be calibrated in terms of monolayers of TMA. Liquid TMA has a density of 0.725 g cm⁻³ and a molar mass of 72.086 g mol⁻¹. The number density of liquid TMA obtained from this density and molar mass is ρ=6.05×10²¹ cm³. Based on this liquid number density, one monolayer of TMA is approximated by ρ^{2/3}=3.32×10¹⁴ cm⁻². Given a mass of 1.197×10⁻²² g for one TMA molecule, the mass of one monolayer of TMA is 39.7 ng cm⁻². This monolayer mass can be used to interpret the QCM mass increases.

The small mass increases of ˜20 ng cm⁻² measured during the initial TMA exposures on PVC are less than one TMA monolayer. These mass increases may result from surface reactions or from absorption of some level of TMA into the polymer bulk. In contrast. the large mass increases of 300, 320 and 460 ng cm⁻² measured during the initial TMA exposures on PP. PMMA and PE, respectively, must be interpreted as TMA absorption into the polymer bulk. These mass increases are consistent with the absorption of between 7-12 TMA monolayers on the QCM sensor.

Given that the original QCM sensor was unpolished and has a higher surface area than the geometric surface area, the mass increases represent TMA coverages of between 5-9 monolayers on or in the polymer films. These large mass increases suggest that TMA can easily permeate into the near surface region of the PP, PMMA and PE polymer films.

The mass changes after the TMA exposures reveal different TMA retention abilities for the various polymers. Although the TMA uptake by PVC is small, the TMA is retained by PVC after the TMA exposures. TMA is also retained by PS after intermediate TMA uptake by PS. Likewise, PE retains most of the TMA even though the TMA uptake by PE is very large. In contrast, PP and PMMA show large TMA uptake but lose most of the TMA after the TMA exposures. This diversity of behavior suggests that there are several parameters that control the amount of TMA uptake and the retention of the TMA by the polymers.

### Chemical Solubility, Free Volume, and Porosity of the Polymer Films

These differences in mass changes and retention ability can be understood in terms of the chemical solubility and free volume of the polymer films. Permeability, P, is controlled by solubility, S, and diffusion, D. Permeability is defined by P=S×D. The large TMA uptake is associated with a large diffusion rate for TMA into the polymer film. The large diffusion rate is believed to result from more highly porous polymer films with large free volume. The retention of the TMA is associated with the chemical solubility of TMA in the polymer film. The chemical solubility is linked with the hydrophobic or hydrophilic nature of the polymer film.

Based on this model, PVC is interpreted to have relatively small TMA uptake because PVC does not have large porosity or free volume. Our disclosed method does work with PVC, but not as well as the method works with the other polymers. The mass increases are consistent with the adsorption or absorption of submonolayer quantities of TMA. These submonolayer quantities are retained after the TMA exposures because the TMA may be strongly adsorbed on the PVC film surface, or the TMA may have a high solubility in the near surface region of the PVC film. In contrast, PP, PMMA and PE are interpreted to have large TMA uptake because they have a large porosity or free volume. PE has a high chemical solubility for TMA and retains the TMA. PMMA does not retain as much TMA because PMMA has a lower chemical solubility for TMA.

These interpretations are consistent with some of the properties of the various polymers. For example, PE is extremely hydrophobic as a result of being composed of only carbon and hydrogen. This highly nonpolar polymer has relatively high chemical solubility for the nonpolar TMA. TMA is reported to have a high solubility in benzene. In contrast, PMMA is more polar because of its carbonyl and oxygen composition resulting from the methyl ester side chain in each monomer unit. This more polar polymer has lower chemical solubility for the nonpolar TMA.

The porosity or free volume of the polymer films is more difficult to characterize. The free volume may be dependent on the spin coating procedure. The free volume is also higher at the surface of most polymer films. Simulations have shown that amorphous polyethylene films have much lower densities and higher diffusivities at their surfaces. Molecular dynamics studies have observed lower densities and a “dynamic interfacial layer” on a free surface of glassy atactic polypropylene. Non-crystalline polymers also have exhibited significant free volumes of up to 10% in the near surface region. The dual presence of amorphous and crystalline regions also affects the rate of diffusion in polymers. A higher diffusion rate has been demonstrated for the amorphous regions due to randonmess of passages in between polymer chains and the fact that crystalline regions are effectively barriers to any diffusion as a result of strong inter-polymer chain bonding.

A Proposed Model for Al₂O₃ ALD Nucleation and Growth on Polymers

The QCM results disclosed herein can be used to formulate a model for Al₂O₃ ALD nucleation and growth on polymers, as represented in FIG. 6A though FIG. 6D. The current QCM and profilometry experiments suggest that Al₂O₃ growth involves the following steps: reactant diffusion, reactant retainment, Al₂O₃ cluster formation, and Al₂O₃ cluster coalescence to form a continuous Al₂O₃ film. Since there are no initial hydroxyl groups within the polymer, the deposition proceeds because TMA molecules are trapped within the near surface region of the polymer film. Subsequent exposure to H₂O leads to reaction with TMA that forms Al₂O₃ nucleation clusters.

As these Al₂O₃ nucleation clusters in the near surface region grow during progressive TMA and H₂O exposures, they fill the space between the polymer chains. They eventually coalesce and close the space between the polymer chains. The Al₂O₃ film becomes nearly continuous. Subsequent exposures lead to progressive Al₂O₃ growth on the underlying polymer film. This continuous film should effectively block further H₂O and TMA reactant diffusion into the near surface region.

By demonstrating Al₂O₃ growth on the PS, PP, PMMA, PE and PVC polymers using the QCM and surface profilometry studies, this model should be fairly general. Additional work in our laboratory for Al₂O₃ ALD on other polymers such as polyethylene napthalene 2,6-dicarboxylate (PEN), Kapton™ and polycarbonate (PC) also confirms the ubiquitousness of this model for Al₂O₃ ALD growth on polymers.

Because various polymers differ in their chemical solubility, porosity, and free volume, and, it is critical to use only certain polymers with the method we claim. The polymers described herein work with our claimed method. The primary distinction of our invention is the initial or nucleation steps, during which TMA is absorbed into the polymers to varying degrees. The nucleation steps typically require 10-15 ALD reaction cycles. After 10-15 cycles, there is a continuous inorganic Al₂O₃ sheet mechanically interlocked to the polymer substrate material. This Al₂O₃ film prevents the precursors from diffusing into the polymer. With the Al₂O₃ barrier on the polymer, the growth then proceeds according to classical ALD in a self-limiting manner.

The mass changes for polymers spin-coated onto QCM sensors revealed a range of behaviors consistent with the varying abilities of the polymers to adsorb, absorb and retain the TMA reactant. The small mass increases during TMA exposures on PVC were consistent with submonolayer TMA adsorption or absorption. The large mass increases during TMA exposures on PP, PMMA and PE were consistent with TMA absorption at quantities of between 5-9 TMA monolayers into the near surface region. Following the TMA exposures, the TMA is either retained or desorbs from the polymer. PS, PVC and PE retained most of the absorbed TMA. In contrast, PP and PMMA lose a large fraction of the absorbed TMA after the TMA exposure.

The retained TMA reactant is available to react with the subsequent H₂O exposure. As shown schematically in FIG. 6A through FIG. 6 D, this reaction is believed to form small Al₂O₃ clusters in the near surface region of the polymer. With successive TMA and H₂O exposures, these Al₂O₃ clusters grow and eventually grow together and form a continuous Al₂O₃ film. The mass changes measured by the QCM reveal that the TMA diffusion into the polymers is impeded after 10-15 AB cycles. At this point, the Al₂O₃ film is believed to form a diffusion barrier on the polymer.

The QCM measurements reveal that Al₂O₃ ALD nucleates and grows readily on certain polymer substrates. This Al₂O₃ ALD growth occurs without specific chemical species that can react with TMA, such as hydroxyl (—OH) groups, on the surface or in the bulk of the polymer.

Following our filing of the Priority patent application, a whole new field of ALD has emerged called “infiltration ALD” that is derived from this phenomena of precursor diffusion into the polymer. Infiltration ALD is currently being used for many applications to make hybrid organic-inorganic materials and for spatial patterning that extends beyond the limits of photolithography.

At the time our invention was made in 2001, one of ordinary skill in the relevant art would NOT expect to see what we discovered. They would not have expected to observe a significant amount of diffusion of ALD precursors into the polymers. They would have been very surprised to see that the diffusion led to Al₂O₃ ALD growth that was much larger than “classic self-limiting ALD growth” for Al₂O₃ ALD.

The expectation of one of ordinary skill in classical atomic layer deposition would have been that the TMA or water would NOT have reacted directly with the polymers we tested, as disclosed herein, or with any polymer that lacked chemical functional groups. It would have been expected that no film would have grown onto the materials because there are no functional groups on the surface. Therefore, the expectation would have been that NO nucleation reactions, e.g. the reaction with TMA or water with the functional groups on the surface, would occur because no functional groups were present in or on the polymer.

If precursor material had been absorbed into the polymer, the purging steps should have eliminated the precursor quickly. It would not have been expected that the TMA or water would have been present in the material to any significant degree after the purging step. Even if the precursor had been desorbing during the next dose, the film should have been made up of large numbers of particles on the surface of the polymer as the desorbing TMA met the incoming water molecules. The particles should have created an aluminum oxide ‘dust’ on the surface of the polymer and the dust would not be well-adhered. In contrast, we have an exceptionally strong bond between the Al₂O₃ and the polymer. In fact, attempts to measure the strength of the bonding have measured the tear strength of the polymers—indicating the inorganic film cannot be removed.

Al₂O₃ ALD on polyethylene (PE) at 85° C. is shown in FIG. 4A for the first 30 AB cycles. FIG. 4B displays the first 5 AB cycles at higher mass resolution. The QCM measures a large mass gain during the first TMA exposure of ˜450 ng cm⁻². This large TMA absorption is followed by a minimal TMA desorption. The mass change decreases to only ˜400 ng cm⁻². The H₂O exposure appears to stop the desorption of any remaining TMA.

Experiments on Polytetrafluoroethylene (PTFE), and Poly(Acrylic Acid) (PAA)

We further tested the ability of trimethyl aluminum (TMA) and water to form aluminum oxide (Al₂O₃) coatings onto Polytetrafluoroethylene (PTFE)—Cat #203 and Poly(acrylic acid) (PAA)—Cat #026 (SP² Scientific Polymer Products).

PAA has the structural formula:

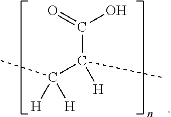

Polytetrafluoroethylene (PTFE) has the structural formula:

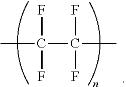

PTFE was selected so that we could examine a polymer without reactive groups in order to ascertain whether or not that the TMA would react with PTFE under ALD conditions and initiate the formation of alumina.

About 50 milligrams of each of the “as received” polymer powders (PAA and PTFE) were placed in separate aluminum weigh boats. In order to minimize any resistance to gases contacting the surfaces of the polymers, a small amount of powder was spread across the bottom of the weigh boat. The weigh boats were both placed in the chamber of a laminar flow style atomic layer deposition reactor. The temperature was increased to 95° C. and held with inert gas flowing over the powders for two (2) hours. The samples were then exposed to 25 cycles of TMA (2 s)/N₂(5 s)/water(1 s)/N₂(5 s) that define the Al₂O₃ ALD. The reactor was cooled to room temperature and the materials were removed from the chamber. Note that the 25 cycles of Al₂O₃ ALD are not sufficient to form an excellent gas diffusion barrier. However, the results from 25 cycles of Al₂O₃ ALD emphasize the difference in the nucleation of Al₂O₃ ALD on the various polymers.

The coated and uncoated resulting powders were then tested in a thermogravimetric analyzer (TGA). This instrument measures mass changes in materials while exposing them to heat and controlled atmosphere. The polymer powders were heated in air to 600° C. We expected that both polymers would combust under these conditions, leaving very little residual mass behind. If an alumina film had grown on a “modified” sample, then the samples exposed to the TMA/water gases would have more residual mass, because the Al₂O₃ will not combust under these conditions, and would serve as a “protective barrier” to the sample. On the other hand, if no alumina film had formed on the “modified” sample, then because the sample would not have been protected by alumina, the residual mass would be less. The results are shown in the table below.

TABLE 2

| | Sample | | |
|---|---|---|---|
| Sample | Mass mg | Mass Loss wt % | Residual Mass % |
| PAA | 31.99 | 99.95 | 0.05 |
| PAA Modified | 50.91 | 97.07 | 2.93 |
| PTFE | 76.09 | 98.8 | 1.20 |
| PTFE Modified | 81.09 | 99.79 | 0.21 |

The table above summarizes the final mass loss in weight percent (wt %) for the PAA and PAA coated with 25 cycles of Al₂O₃ ALD. The PAA coated with 25 cycles of Al₂O₃ ALD demonstrated a significantly higher residual mass (>50×) than the as received material. There is still significant mass loss because an Al₂O₃ ALD film grown using only 25 cycles of Al₂O₃ ALD is not an excellent gas diffusion barrier. However, there is residual mass remaining from the Al₂O₃ ALD coating and there also may be some protection from the Al₂O₃ ALD coating.

This behavior is in contrast to the PTFE where the residual mass of the as received material is actually higher than the PTFE coated with 25 cycles of Al₂O₃ ALD. This result indicates that, to the extent measurable, the PTFE was not coated as extensively by the Al₂O₃ ALD as the PAA was coated by the Al₂O₃ ALD. These results indicate that the PTFE was not coated. We conclude that the PTFE and did not absorb the TMA and thus did not behave according to our method.

### Experiments on Block Copolymer, Fluorinated Ethylene Propylene (FEP) and KAPTON

Aluminum oxide coatings were performed on DuPont™ Teflon® FEP and Kapton H thin film samples. Kapton, poly(4,4′-oxydiphenylene-pyromellitimide), is a typical polyimide and is produced by condensation of a pyromellitic dianhydride, e.g.,

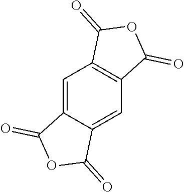 [SMILES: O=c1oc(=O)c2cc3c(=O)oc(=O)c3cc12]

and 4,4′-oxydianiline, which has the structure:

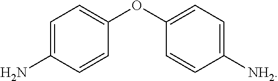 [SMILES: Nc1ccc(Oc2ccc(N)cc2)cc1]

The general structure of Kapton is:

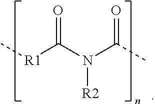

Neither FEP nor Kapton H could be easily spin-coated for detailed QCM studies. Therefore, an alternate testing mechanism was devised: First, thin films of each polymer were coated with various thicknesses of Al₂O₃ by ALD. The polymer films were then exposed to hyperthermal oxygen and we observed the erosion of the film. In these experiments, Kapton H and Teflon FEP thin film samples were obtained from NASA and coated with Al₂O₃ ALD (trimethyl aluminum/water) in ALD reactors at the University of Colorado.

Al₂O₃ layers of various thicknesses were deposited on 1″ squares of Kapton H and Teflon FEP. The Al₂O₃ ALD-coated samples, as well as uncoated Kapton and Teflon, were then exposed to a hyperthermal oxygen beam at Montana State University. Average energies of the hyperthermal O-atom beam were in the 5.3-5.5 eV range. After the exposure, the samples were examined with FE-SEM. If erosion was detected, the depth of the erosion was measured with profilometry. Results on Kapton H and Teflon FEP are summarized below, Table 3:

TABLE 3

| Kapton Sample Composition | |
|---|---|
| Uncoated Kapton | 8.11 ± 0.23 μm erosion |
| Kapton with 13 cycles Al₂O₃ | 6.88 ± 0.40 μm erosion |
| Kapton with 17 cycles Al₂O₃ | Slight erosion. |
| Kapton with 25 cycles Al₂O₃ | No erosion. |
| Kapton with 40 cycles Al₂O₃ | No erosion. |

These results showed excellent protection of the Kapton H polymer used on space vehicles with only 25 AB cycles of Al₂O₃ ALD.

TABLE 4
Results on Teflon FEP:

| Teflon FEP Sample Composition | |
|---|---|
| Uncoated Teflon FEP | 1.40 ± 0.20 μm erosion |
| FEP with 13 cycles Al₂O₃ | 1.26 ± 0.15 μm erosion |
| FEP with 17 cycles Al₂O₃ | 1.24 ± 0.14 μm erosion. |
| FEP with 25 cycles Al₂O₃ | 1.22 ± 0.14 μm erosion. |
| FEP with 40 cycles Al₂O₃ | 1.10 ± 0.14 μm erosion. |

These results showed no protection of Teflon FEP surface with up to 40 cycles of Al₂O₃ ALD. The erosion measurements for the coated samples are all within the error of the uncoated sample.

Conclusion: The difference in number of ALD cycles required to achieve protection of the different polymers is likely a due to more difficult nucleation of Al₂O₃ ALD films on the low porosity, low free volume, hydrophobic Teflon (—CF₂—)ₙ compared with Kapton poly(4,4′-oxydiphenylene-pyromellitimide). The traditional ALD reactions apparently cannot be carried out easily on the Teflon surface. The experiment demonstrates that there is little or no diffusion and absorption of either TMA or water into the Teflon, and therefore no alumina is coated on the Teflon. This is in contrast to the diffusion, absorption, and nucleation that occurs in other polymers such as polyethylene and Kapton.

### EQUIVALENTS

While this invention has been particularly shown and described with references to preferred embodiments thereof, it will be understood by those skilled in the art that various changes in form and details may be made therein without departing from the scope of the invention encompassed by the appended claims.

What is claimed is:

1. A composition comprising:
a polymer substrate having free volume and/or a porous surface; and
an inorganic film layer comprising a metal oxide or nitride at least partially covering the polymer substrate.

2. The composition of claim 1, wherein the inorganic film layer is conformal.

3. The composition of claim 1, wherein the thickness of the inorganic film layer is about 200 nanometers or less.

4. The composition of claim 1, wherein the thickness of the inorganic film layer is from about 0.1 nanometer to about 50 nanometers.

5. The composition of claim 1, wherein the thickness of the inorganic film layer is from about 0.5 nanometer to about 35 nanometers.

6. The composition of claim 1, wherein the thickness of the inorganic film layer is from about 1 nanometer to about 20 nanometers.

7. The composition of claim 1, wherein the inorganic film layer comprises at least one of aluminum oxide, titanium oxide, zinc oxide, or a combination thereof.

8. The composition of claim 1, wherein the polymer substrate comprises polyethylene or a derivative thereof.

9. The composition of claim 1, wherein the polymer substrate comprises polypropylene or a derivative thereof.

10. The composition of claim 1, wherein the polymer substrate comprises polymethyl methacrylate or a derivative thereof.

11. The composition of claim 1, wherein the polymer substrate comprises polystyrene or a derivative thereof.

12. The composition of claim 1, wherein the polymer substrate comprises polycarbonate or a derivative thereof.

13. The composition of claim 1, wherein the polymer substrate comprises poly(1-trimethylsilyl propene) or a derivative thereof.

14. The composition of claim 1, wherein the polymer substrate comprises at least one of ethylene homopolymers, propylene homopolymers, ethylene-butene copolymers, ethylene-hexene copolymers, and ethylene-methacrylate copolymers.

15. The composition of claim 1, wherein the polymer substrate comprises at least one of polyvinylidene fluoride, polysulfones, polyether sulfones, polyesters, polyacetals, polyamides, polyimides, polyether ether ketones, polyphenylene oxides, polyphenylene sulfides, polyethylene naphthalates, and a mixture of inorganic particles with a binder polymer.

16. The composition of claim 1, wherein the polymer substrate is poly(4,4′-oxydiphenylene-pyromellitimide).

17. The composition of claim 1, wherein the polymer substrate is in the form of a particulate.

18. The composition of claim 1, wherein the film layer comprising a metal oxide or nitride is deposited by atomic layer deposition.

19. The composition of claim 18, wherein the atomic layer deposition is carried out in a fluidized bed reactor.

20. The composition of claim 18, wherein the atomic layer deposition is carried out in a rotary bed rector or a vibrating bed reactor.

21. The composition of claim 1, wherein the composition is fabricated into a container.

22. The composition of claim 21, wherein the inorganic film layer provides a gas and vapor diffusion barrier for the container.

23. The composition of claim 1, for use in space vehicles, wherein the inorganic film layer is positioned to deflect atoms, photons, and/or ions striking the composition.
